(19) United States
(12) Patent Application Publication
(10) Pub. No.: US 2025/0159952 A1
(43) Pub. Date: May 15, 2025

(54) SEMICONDUCTOR DEVICE

(71) Applicant: Samsung Electronics Co., Ltd., Suwon-si (KR)

(72) Inventors: Jaeyoung Lim, Suwon-si (KR); HANSEONG KIM, Suwon-si (KR); DONGHYUN ROH, Suwon-si (KR); JoonYong Bae, Suwon-si (KR); GYUHWAN AHN, Suwon-si (KR); JANGHO LEE, Suwon-si (KR)

(21) Appl. No.: 18/659,659

(22) Filed: May 9, 2024

(30) Foreign Application Priority Data
Nov. 9, 2023 (KR) 10-2023-0154468

(51) Int. Cl. H01L 29/06; H01L 29/08; H01L 29/423; H01L 29/775; H01L 29/786

(52) U.S. Cl. CPC H10D 62/121; H10D 30/43; H10D 30/6735; H10D 30/6757; H10D 62/151

(57) ABSTRACT

A semiconductor device including an active pattern located on a substrate, spaced apart from other active patterns in a first direction and extending in a second direction different from the first direction; source/drain patterns located on the active pattern and each source drain pattern spaced apart from one another in the second direction; a channel pattern located between adjacent source/drain patterns; a gate pattern extending between the adjacent source/drain patterns in the first direction and surrounding at least a portion of the channel pattern; and an isolation structure extending in the first direction, the isolation structure located outside the source/drain pattern in the second direction and extending into the active pattern in a third direction different from the first and second directions, in which the isolation structure includes insulating patterns stacked in the third direction, an interfacial layer located between insulating patterns, and an insulating liner surrounding the insulating patterns.

### CROSS-REFERENCE TO RELATED APPLICATION

This application claims priority under 35 U.S.C § 119 to, and the benefit of, Korean Patent Application No. 10-2023-0154468 filed in the Korean Intellectual Property Office on Nov. 9, 2023, the entire contents of which are incorporated herein by reference.

### BACKGROUND OF THE INVENTION

### (a) Field of the Invention

The present disclosure relates to a semiconductor device, and more particularly, to a transistor including nanowires or nanosheets, or a fin-type transistor including a channel pattern with a fin-type pattern shape.

### (b) Description of the Related Art

A semiconductor is a material belonging to an intermediate region between a conductor and a nonconductor, and refers to a material that conducts electricity under certain conditions. Various semiconductor devices may be manufactured by using these semiconductor materials, and for example, memory devices and the like may be manufactured. Such semiconductor devices May be used in various electronic devices.

As the electronic industry progressively develops, demands on the properties of semiconductor devices are gradually increasing. For example, demands for high reliability, high speed, and/or multifunctionality of semiconductor devices are gradually increasing. In order to satisfy these required characteristics, structures within semiconductor devices are becoming increasingly complex and integrated.

### SUMMARY OF THE INVENTION

The present disclosure provides a semiconductor device which includes an isolation structure without voids or seams, thereby preventing certain defects, such as separation of the isolation structure, and preventing oxygen (O) or carbon (C) from being diffused from the isolation structure to a channel pattern and causing adverse effects.

An embodiment of the present disclosure provides a semiconductor device including: an active pattern located on a substrate, the active pattern spaced apart from other active patterns in a first direction and extending in a second direction different from the first direction; source/drain patterns located on the active pattern and each source/drain pattern spaced apart from one another in the second direction; a channel pattern located between a first source/draion pattern and a second/source drain pattern among the source/drain patterns; a gate pattern extending between the first source/draion pattern and the second source/drain pattern in the first direction and surrounding at least a portion of the channel pattern; and an isolation structure extending in the first direction, the isolation structure located outside the source/drain patterns in the second direction and extending into the active pattern in a third direction that is different from the first and second directions, the isolation structure includes insulating patterns stacked in the third direction, an interfacial layer located between insulating patterns, and an insulating liner surrounding the insulating patterns. Another embodiment of the present disclosure provides a semiconductor device including: an active pattern located on a substrate, the active pattern spaced apart in a first direction from other active patterns and extending in a second direction different from the first direction; source/drain patterns located on the active pattern and spaced apart from one another in the second direction; a channel pattern located between adjacent source/drain patterns; a gate pattern extending between the source/drain patterns of the adjacent source drain patterns in the first direction and surrounding at least a portion of the channel pattern; and an isolation structure extending in the first direction, located outside the source/drain pattern in the second direction, and extending into the active pattern in a third direction that is different from the first and second directions, wherein the isolation structure includes insulating patterns stacked in the third direction, an interfacial layer located between the insulating patterns, an insulating liner surrounding the insulating patterns, and an insulating spacer located between adjacent insulating patterns and the insulating liner.

Still another embodiment of the present disclosure provides a semiconductor device including: an active pattern located on a substrate, the active pattern spaced apart from other active patterns in a first direction and extending in a second direction different from the first direction; source/drain patterns located on the active pattern and spaced apart from one another in the second direction; a channel pattern located between a first source/draion pattern and a second/source drain pattern among the source/drain patterns; a gate pattern extending between the first source/draion pattern and the second/source drain pattern source/drain patterns in the first direction and surrounding at least a portion of the channel pattern; and an isolation structure extending in the first direction, the isolation structure located outside the source/drain pattern in the second direction, and extending into the active pattern in a third direction that is different from the first and second directions, wherein the isolation structure includes an insulating structure having a first portion and a second portion having different contents (atom %) of at least one of oxygen (O) and carbon (C), and an insulating liner surrounding the insulating structure.

The semiconductor device according to the embodiments includes an isolation structure without voids or seams, thereby preventing certain defects, such as separation of the isolation structure, and preventing oxygen (O) or carbon (C) from being diffused from the isolation structure to a channel pattern and causing adverse effects.

### BRIEF DESCRIPTION OF THE DRAWINGS

FIG. 1 is a top plan view of a semiconductor device according to an embodiment.

FIG. 2 is a cross-sectional view taken along line A-A′ of FIG. 1.

FIG. 3 is a cross-sectional view taken along line B-B′ of FIG. 1.

FIG. 4 is a cross-sectional view taken along line C-C′ of FIG. 1.

FIG. 5 is a cross-sectional view taken along line D-D′ of FIG. 1.

FIG. 6 is a cross-sectional view of enlarged region P of FIG. 2.

FIG. 7 is a cross-sectional view corresponding to FIG. 6 for another embodiment.

FIG. 8 is a cross-sectional view illustrating a method of manufacturing a semiconductor device according to an embodiment.

FIG. 9 is a cross-sectional view illustrating a method of manufacturing a semiconductor device according to an embodiment.

FIG. 10 is a cross-sectional view illustrating a method of manufacturing a semiconductor device according to an embodiment.

FIG. 11 is a cross-sectional view illustrating a method of manufacturing a semiconductor device according to an embodiment.

FIG. 12 is a cross-sectional view illustrating a method of manufacturing a semiconductor device according to an embodiment.

FIG. 13 is a cross-sectional view illustrating a method of manufacturing a semiconductor device according to an embodiment.

FIG. 14 is a cross-sectional view illustrating a method of manufacturing a semiconductor device according to an embodiment.

FIG. 15 is a cross-sectional view illustrating a method of manufacturing a semiconductor device according to an embodiment.

FIG. 16 is a cross-sectional view illustrating a method of manufacturing a semiconductor device according to an embodiment.

FIG. 17 is a cross-sectional view illustrating a method of manufacturing a semiconductor device according to an embodiment.

FIG. 18 is a cross-sectional view illustrating a method of manufacturing a semiconductor device according to an embodiment.

FIG. 19 is a cross-sectional view illustrating a method of manufacturing a semiconductor device according to an embodiment.

FIG. 20 is a cross-sectional view illustrating a method of manufacturing a semiconductor device according to an embodiment.

FIG. 21 is a cross-sectional view illustrating a method of manufacturing a semiconductor device according to an embodiment.

FIG. 22 is a cross-sectional view illustrating a method of manufacturing a semiconductor device according to an embodiment.

FIG. 23 is a cross-sectional view illustrating a method of manufacturing a semiconductor device according to an embodiment.

FIG. 24 is a cross-sectional view illustrating a method of manufacturing a semiconductor device according to an embodiment.

FIG. 25 is a cross-sectional view illustrating a method of manufacturing a semiconductor device according to an embodiment.

FIG. 26 is a cross-sectional view illustrating a method of manufacturing a semiconductor device according to an embodiment.

FIG. 27 is a cross-sectional view illustrating a method of manufacturing a semiconductor device according to an embodiment.

FIG. 28 is a cross-sectional view illustrating a method of manufacturing a semiconductor device according to an embodiment.

FIG. 29 is a cross-sectional view illustrating a method of manufacturing a semiconductor device according to an embodiment.

FIG. 30 is a cross-sectional view illustrating a method of manufacturing a semiconductor device according to an embodiment.

FIG. 31 is a cross-sectional view illustrating a method of manufacturing a semiconductor device according to an embodiment.

FIG. 32 is a cross-sectional view illustrating a method of manufacturing a semiconductor device according to an embodiment.

FIG. 33 is a cross-sectional view illustrating a method of manufacturing a semiconductor device according to an embodiment.

FIG. 34 is a cross-sectional view illustrating a method of manufacturing a semiconductor device according to another embodiment.

FIG. 35 is a cross-sectional view illustrating a method of manufacturing a semiconductor device according to another embodiment.

FIG. 36 is a cross-sectional view illustrating a method of manufacturing a semiconductor device according to another embodiment.

FIG. 37 is a cross-sectional view illustrating a method of manufacturing a semiconductor device according to another embodiment.

### DETAILED DESCRIPTION OF THE EMBODIMENTS

Hereinafter, embodiments of the present inventive concept will be described with reference to accompanying drawings so as to be easily understood by a person ordinary skilled in the art. The present inventive concept may be implemented in various embodiments and embodiments are not limited to the following described embodiments.

The drawings and description are to be regarded as illustrative in nature and not restrictive. Like reference numerals designate like elements throughout the specification.

In addition, the size and thickness of each configuration illustrated in the drawings are arbitrarily illustrated for understanding and ease of description, but the present disclosure is not limited thereto. In the drawings, the thickness of layers, films, panels, regions, etc., are exaggerated for clarity. In the drawings, for understanding and ease of description, the thickness of some layers and areas is exaggerated.

Further, it will be understood that when an element such as a layer, film, region, or substrate is referred to as being “on” another element, it may be directly on the other element or intervening elements may also be present. When an element is referred to as being “directly on” another element, there are no intervening elements present.

In addition, unless explicitly described to the contrary, the word “include”, and variations such as “includes” or “including”, will be understood to imply the inclusion of stated elements but not the exclusion of any other elements. Further, in the entire specification, when it is referred to as “in a plan view”, it means when a target part is viewed from above, and when it is referred to as “in a cross-sectional view”, it means when the cross-section obtained by cutting a target part vertically is viewed from the side.

Also, throughout the specification, two directions parallel to an upper surface of a substrate and intersecting one another are defined as a first direction D1 and a second direction D2, respectively, and a direction perpendicular to the upper surface of the substrate is described as a third direction D3. In one example, the first direction D1 and the second direction D2 may be orthogonal to each other.

The drawings of the semiconductor device according to the embodiment illustrate, but are not limited to, transistors including nanowires or nanosheets, multi-bridge channel field effect transistors (MBCFET™), and fin-type transistors (FinFETs) including channel regions shaped in a fin-like pattern. Semiconductor devices according to some embodiments may include tunneling transistors, 3D stack field effect transistors (3DSFETs), complementary field effect transistors (CFETs), and the like.

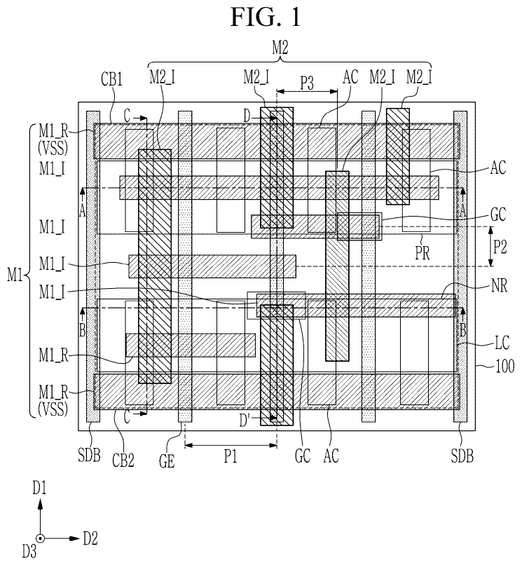

Hereinafter, a semiconductor device according to an embodiment will be described with reference to FIGS. 1 to 6.

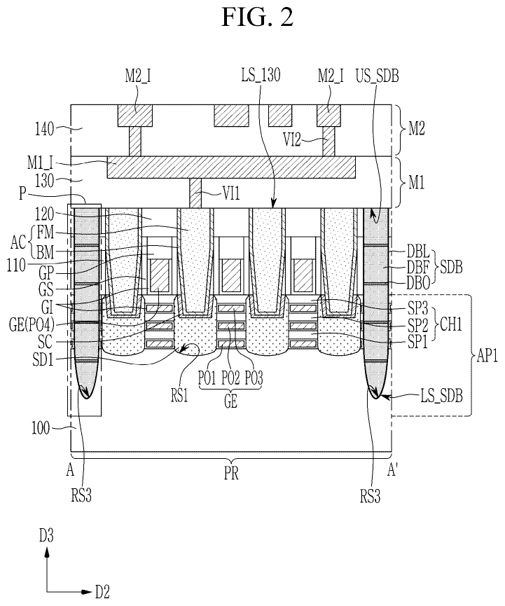

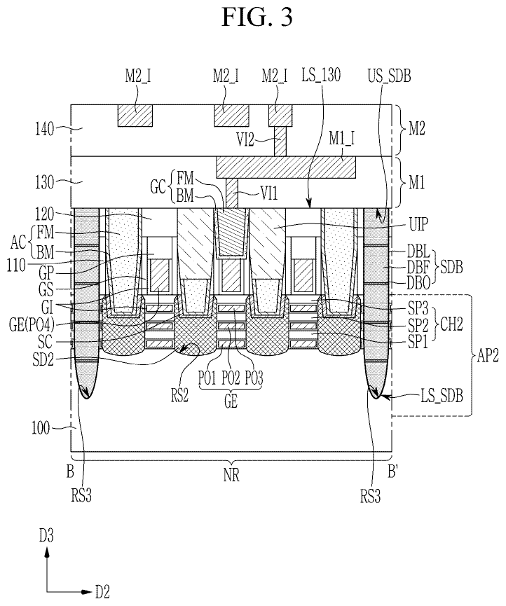

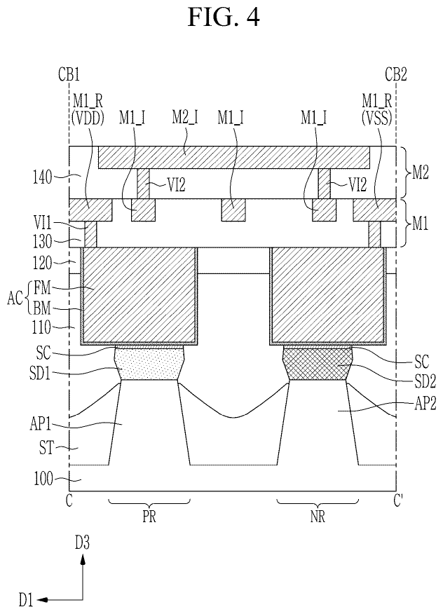

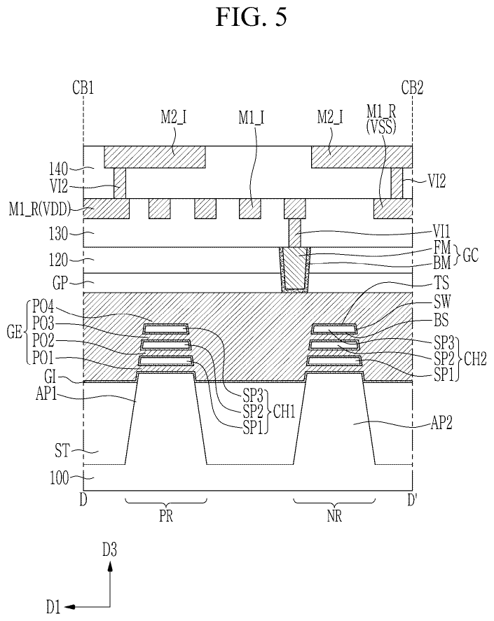

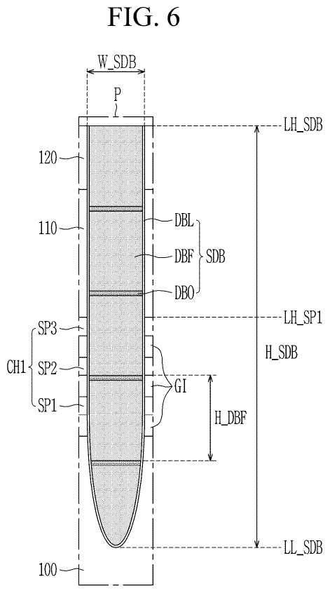

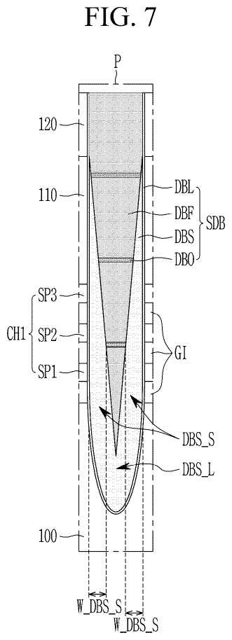

FIG. 1 is a top plan view of a semiconductor device according to an embodiment. FIG. 2 is a cross-sectional view taken along line A-A′ of FIG. 1. FIG. 3 is a cross-sectional view taken along line B-B′ of FIG. 1. FIG. 4 is a cross-sectional view taken along line C-C′ of FIG. 1. FIG. 5 is a cross-sectional view taken along line D-D′ of FIG. 1. FIG. 6 is a cross-sectional view of enlarged region P of FIG. 2. FIG. 7 is a cross-sectional view corresponding to FIG. 6 for another embodiment.

For clear understanding and simple illustration, FIG. 1 mainly illustrates an isolation structure SDB, a first cell boundary CB1, a second cell boundary CB2, a first metal layer M1, a second metal layer M2, a gate pattern GE, an active contact AC, and a gate contact GC.

Referring to FIGS. 1 to 6, a logic cell LC may be provided on a substrate 100. On the logic cell LC, logic transistors configuring a logic circuit may be disposed. As used herein, the term “logic cell” may refer to a unit circuit configured to perform a single logical operation and be composed of a plurality of interconnected MOSFETs. Examples of logic cells include a NAND gate, a NOR gate, an inverter, and a latch. In addition, it will be apparent that the invention is not limited to one or a plurality of logic cells, but may be implemented in connection with one or more transistors, a portion of a transistor, an integrated circuit (e.g., comprising a plurality of interconnected logic cell), a semiconductor chip, a plurality of semiconductor chips (e.g., stacked in a package), etc.

In one example, the substrate 100 may be a semiconductor substrate formed of and/or including silicon, germanium, or silicon-germanium, or a compound semiconductor substrate. In another example, the substrate 100 may be an insulating substrate formed of and/or including an insulating material.

The logic cell LC may include a PMOSFET region PR and an NMOSFET region NR. The PMOSFET region PR and the NMOSFET region NR may be defined by first and second active patterns AP1 and AP2 located on the substrate 100. For example, the first and second active patterns AP1 and AP2 may be disposed in the PMOSFET region PR and the NMOSFET region NR, respectively.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

As used herein, the singular forms “a”, “an” and “the” are intended to include the plural forms as well, unless the context clearly indicates otherwise.

As used herein, the term “and/or” includes any and all combinations of one or more of the associated listed items and may be abbreviated as “/”.

The first and second active patterns AP1 and AP2 may be portions of the logic cell LC that protrude from the substrate 100 in the third direction D3. The first and second active patterns AP1 and AP2 may be spaced apart in the first direction D1. The first and second active patterns AP1 and AP2 may extend in the second direction D2.

In one example, the first and second active patterns AP1 and AP2 may be formed of and/or include an elemental semiconductor material, such as silicon (Si) or germanium (Ge). Further, the first and second active patterns AP1 and AP2 may be formed of and/or include compound semiconductors, for example, group IV-IV compound semiconductors or group III-V compound semiconductors. The group IV-IV compound semiconductor may be a binary compound or a ternary compound including, for example, at least two of carbon (C), silicon (Si), germanium (Ge), tin (Sn), or a combination thereof. A group III-V compound semiconductor may be, for example, a binary compound, ternary compound, or tetrameric compound formed by combining at least one of the group Ill elements of aluminum (Al), gallium (Ga), and indium (In) with one of the group V elements of phosphorus (P), arsenic (As), antimony (Sb) or a combination thereof. As another example, the active pattern AP may also be an insulating pattern including an insulating material.

A device isolation layer ST may be located between the first and second active patterns AP1 and AP2. For example, the device isolation layer ST may be located next to the first and second active patterns AP1 and AP2 in the first direction D1. The device isolation layer ST may fill trenches between the first and second active patterns AP1 and AP2.

The upper surfaces of the first and second active patterns AP1 and AP2 may protrude in the third direction D3 from the upper surface of the device isolation layer ST. For example, the device isolation layer ST may not cover the upper portions of the first and second active patterns AP1 and AP2. The device isolation layer ST may cover the sidewalls of the first and second active patterns AP1 and AP2 in the first direction D1.

In one example, the device isolation layer ST may be formed of and/or include an insulating material, for example, silicon nitride (SiN), silicon nitroxide (SiON), or a combination thereof. While the device isolation layer ST is shown as a single layer, embodiments of the inventive concept are not limited thereto and the device isolation layer ST may include a multilayer in which layers of a plurality of layers are stacked.

The first active pattern AP1 may include a first channel pattern CH1 in an upper portion thereof. The second active pattern AP2 may include a second channel pattern CH2 in an upper portion thereof. In one example, the first and second channel patterns CH1 and CH2 may be formed of and/or include a semiconductor material and have a nanosheet shape having a thickness of several nanometers. For example, each of the first and second channel patterns CH1 and CH2 may include a first semiconductor pattern SP1, a second semiconductor pattern SP2, and a third semiconductor pattern SP3 stacked sequentially. The first to third semiconductor patterns SP1, SP2, and SP3 may be spaced apart from each other in the third direction D3.

In the example embodiment of FIGS. 3 and 5, it is illustrated that there are three first to third semiconductor patterns SP1, SP2, and SP3 stacked while being spaced apart along the third direction D3, but the embodiments of the inventive concept are not limited thereto. For example, in some embodiments two semiconductor patterns may be stacked while being spaced apart along the third direction D3, or four or more semiconductor patterns may be stacked while being spaced apart along the third direction D3.

In addition, FIGS. 3 and 5 illustrate that the sides of the first and third semiconductor patterns SP1, SP2, and SP3 are planar, but embodiments of the inventive concept are not limited thereto. For example, the sides of the first through third semiconductor patterns SP1, SP2, and SP3 may be a combination of curved and flat surfaces, or may be entirely curved.

Each of the first and second channel patterns CH1 and CH2 may be formed of and/or include an elemental semiconductor material, such as silicon (Si), silicon germanium (SiGe), a group IV-IV compound semiconductor, or a group III-V compound semiconductor. Each of the first and second channel patterns CH1 and CH2 may include the same material as the first and second active patterns AP1 and AP2, or may include a different material from the first and second active patterns AP1 and AP2.

A plurality of first recesses RS1 may be formed in an upper portion of the first active pattern AP1. A first source/drain pattern SD1 may be disposed within each of the first recess RS1. The first source/drain pattern SD1 may be an impurity region of a first conductive type (for example, p-type). A first channel pattern CH1 may be interposed between a pair of adjacent first source/drain patterns SD1. For example, the stacked first to third semiconductor patterns SP1, SP2, and SP3 may connect a pair of first source/drain patterns SD1 to each other.

A plurality of second recesses RS2 may be formed on the upper portion of the second active pattern AP2. A second source/drain pattern SD2 may be disposed within each of the second recesses RS2. The second source/drain pattern SD2 may be impurity regions of a second conductive type (for example, n-type). The second conductive type may be different than the first conductive type. A second channel pattern CH2 may be interposed between a pair of adjacent second source/drain patterns SD2. For example, the stacked first to third semiconductor patterns SP1, SP2, and SP3 may connect a pair of second source/drain patterns SD2 to each other.

In one example, the first and second source/drain patterns SD1 and SD2 may be epitaxial patterns formed by a selective epitaxial growth (SEG) process. The upper surface of each of the first and second source/drain patterns SD1 and SD2 may be located substantially at the same level as the upper surface of the third semiconductor pattern SP3. Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise. In some embodiments, the upper surface of each of the first and second source/drain patterns SD1 and SD2 may be higher than the upper surface of the third semiconductor pattern SP3.

In one example, the first source/drain pattern SD1 may include a first semiconductor layer and a second semiconductor layer on the first semiconductor layer.

The first semiconductor layer may cover the inner wall of the first recess RS1. The thickness of the first semiconductor layer may decrease from a lower portion to an upper portion thereof. For example, the thickness in the third direction D3 of the first semiconductor layer at the bottom of the first recess RS1 may be greater than the thickness in the second direction D2 of the first semiconductor layer at the top of the first recess RS1. The first semiconductor layer may have a U-shape along the profile of the first recess RS1.

The second semiconductor layer may fill the remaining region of the first recess RS1 excluding the first semiconductor layer. The volume of the second semiconductor layer may be larger than the volume of the first semiconductor layer. For example, the ratio of the volume of the second semiconductor layer to the total volume of the first source/drain pattern SD1 may be greater than the ratio of the volume of the first semiconductor layer to the total volume of the first source/drain pattern SD1.

Each of the first semiconductor layer and the second semiconductor layer may be formed of and/or include silicon-germanium (SiGe). In one example, the first semiconductor layer may be formed of and/or include a relatively low concentration of germanium (Ge). In some embodiments, the first semiconductor layer may be formed of and/or include only silicon (Si), excluding germanium (Ge). The concentration of germanium (Ge) in the first semiconductor layer may be in the range of 0 at % to 10 at %.

The second semiconductor layer may include a relatively high concentration of germanium (Ge). In one example, the concentration of germanium (Ge) in the second semiconductor layer may be in the range of 30 at % to 70 at %. The concentration of germanium (Ge) in the second semiconductor layer may increase toward the third direction D3. For example, a portion of the second semiconductor layer adjacent to the first semiconductor layer may have a germanium (Ge) concentration of about 40 at %, while an upper portion of the second semiconductor layer may have a germanium (Ge) concentration of about 60 at %.

The first and second semiconductor layers may include impurities (for example, boron) that cause the first source/drain pattern SD1 to have a p-type. The concentration (for example, atomic percent) of the impurities in the second semiconductor layer may be greater than the concentration of the impurities in the first semiconductor layer.

The gate pattern GE extends in the first direction D1 across the first and second active patterns AP1 and AP2. The gate patterns GE may be arranged in the second direction D2 and may be spaced apart by a first pitch P1. Each gate pattern GE may be superimposed on the first and second channel patterns CH1 and CH2 in the third direction D3.

In one example, the gate pattern GE may include a first portion PO1 interposed between each of the first and second active patterns AP1 and AP2 and the first semiconductor pattern SP1 of the respecctive first and second active pattern, a second portion PO2 interposed between the first semiconductor pattern SP1 of the respecctive first and second active pattern and the second semiconductor pattern SP2 of the respecctive first and second active pattern, a third portion PO3 interposed between the second semiconductor pattern SP2 of the respecctive first and second active pattern and the third semiconductor pattern SP3 of the respecctive first and second active pattern, and a fourth portion PO4 on the third semiconductor pattern SP3 of the respecctive first and second active pattern.

The gate pattern GE may be disposed on an upper surface TS, a lower surface BS, and both sidewalls SW of each of the first to third semiconductor patterns SP1, SP2, and SP3. For example, the gate electrode GE may enclose at least a portion of the first and second channel patterns CH1 and CH2.

A pair of gate spacers GS may be disposed on the both sidewalls of the fourth portion PO4 of the gate pattern GE (e.g., sidewalls normal to D2). The gate spacers GS may extend in the first direction D1 along the gate pattern GE. An upper surface of the gate spacer GS may be higher than an upper surface of the gate pattern GE. The upper surface of the gate spacers GS may be substantially at the same level as the upper surface of a first interlayer insulating layer 110, which will be described later. The gate spacer GS may be formed of and/or include SiCN, SiCON, SIN, or a combination thereof. Further, the gate spacer GS may include a multi-layer of SiCN, SiCON, SIN, or a combination thereof.

A gate capping pattern GP may be disposed on the gate pattern GE. The gate capping pattern GP may extend in the first direction D1 along the gate pattern GE. The gate capping pattern GP may be formed of and/or include a material that is etch selective for the first and second interlayer insulating layers 110 and 120, which will be described below. In one example, the gate capping pattern GP may be formed of and/or include SiON, SiCN, SiCON, SiN, or a combination thereof.

A gate insulating layer GI may be interposed between the gate pattern GE and the first channel pattern CH1 and between the gate pattern GE and the second channel pattern CH2. The gate insulating layer GI may cover the upper surface TS, the lower surface BS, and the both sidewalls SW of each of the first to third semiconductor patterns SP1, SP2, and SP3. The gate insulating layer GI may cover the upper surface of the device isolation layer ST below the gate pattern GE.

The gate insulator GI may include a silicon oxide film, a silicon nitride film, a high dielectric constant film, or a combination thereof. The high dielectric constant film may be formed of and/or include a high dielectric material having a higher dielectric constant than that of the silicon oxide film. In one example, the high dielectric constant material may include hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, lead zinc niobate, or a combination thereof.

In some embodiments, the gate pattern GE may include a first metal pattern and a second metal pattern on the first metal pattern. The first metal pattern may be disposed on the gate insulating layer GI and may be adjacent to the first to third semiconductor patterns SP1, SP2, and SP3. The first metal pattern may include metal having a work function that regulates a threshold voltage of the transistor. The thickness and composition of the first metal pattern may be adjusted to achieve a desired threshold voltage of the transistor. For example, the first to third portions PO1, PO2, and PO3 of the gate pattern GE may include a first metal pattern having a metal with a work function for regulating the threshold voltage of the transistor.

The first metal pattern may be formed of and/or include a metal nitride film. For example, the first metal pattern may be formed of and/or include titanium (Ti), tantalum (Ta), aluminum (AI), tungsten (W), molybdenum (Mo), or a combination thereof. The first metal pattern may further include carbon (C). The first metal pattern may include a plurality of stacked metal films having the work work function for regulating the threshold voltage of the transistor.

The second metal pattern may be formed of and/or include a metal that has lower electrical resistance compared to that of the first metal pattern. For example, the second metal pattern may be formed of and/or include a metal including tungsten (W), aluminum (AI), titanium (Ti), tantalum (Ta), or a combination thereof. For example, the fourth portion PO4 of the gate pattern GE may include a first metal pattern and a second metal pattern on the first metal pattern.

Additionally, although not shown, inner spacers may be located on the NMOSFET region NR. The inner spacers may be interposed between the first to third portions PO1, PO2, and PO3 of the gate electrode GE and the second source/drain pattern SD2, respectively. The inner spacers may be in contact with the second source/drain pattern SD2. Each of the first to third portions PO1, PO2, and PO3 of the gate electrode GE may be spaced apart from the second source/drain pattern SD2 by an inner spacer.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

The first interlayer insulating layer 110 may be disposed on the substrate 100. The first interlayer insulating layer 110 may cover the first and second source/drain patterns SD1 and SD2. An upper surface of the first interlayer insulating layer 110 may be located substantially at the same level as an upper surface of the gate capping pattern GP and an upper surface of the gate spacer GS.

A second interlayer insulating layer 120 covering the gate capping pattern GP may be disposed on the first interlayer insulating layer 110. In one example, the first and second interlayer insulating layers 110 and 120 may include a silicon oxide film.

Referring again to FIGS. 1 to 3, a pair of isolation structures SDBs may be disposed on opposite sides of the logic cell LC opposing each other in the second direction D2. For example, the pair of isolation structures SDBs may be located on the outer sides of the first and second source/drain patterns SD1 and SD2 located on opposite sides of the logic cell LC in the second direction D2.

The isolation structure SDB may extend along the gate pattern GE in the first direction D1. The pitch between the isolation structure SDB and an adjacent gate pattern GE may be the same as the first pitch P1. The isolation structure SDB may be disposed opposite the gate pattern GE with the first and second source/drain patterns SD1 and SD2 interpose therebetween. For example, the first and second source/drain patterns SD1 and SD2 may be located between the isolation structure SDB and the gate pattern GE.

In FIGS. 1 to 3, it is illustrated that four first and second source/drain patterns SD1 and SD2 and three gate patterns GE are disposed between the pair of isolation structures SDBs, but embodiments of the inventive concept are not limited thereto, and depending on the configuration of the logic cell LC, the number of first and second source/drain patterns SD1 and SD2 and gate patterns GE disposed between the pair of isolation structures SDBs may vary, and for example, the number of each of the first and second source/drain patterns SD1 and SD2 and gate patterns GE disposed between the pair of isolation structures SDBs may be one or more, two or more, three or more, four or more, five or more, six or more, seven or more, eight or more, nine or more, or ten or more, or ten or less, nine or less, eight or less, seven or less, six or less, five or less, four or less, three or less, or two or less.

The isolation structure SDB may extend into the first and second active patterns AP1 and AP2 in the third direction D3. The first and second active patterns AP1 and AP2 may have first and second surfaces that are opposed in the third direction D3. The first surfaces of the first and second active patterns AP1 and AP2 is located closer to the substrate 100 than the second surface. For example, the first surfaces of the first and second active patterns AP1 and AP2 may be lower surfaces and the second surfaces of the first and second active patterns AP1, AP2 may be upper surfaces. Further, the isolation structure SDB may have a first surface a second surface facing the third direction D3. The first surface of the isolation structure SDB is located closer to the substrate 100 than the second surface. For example, the first surface of the isolation structure SDB may be a lower surface LS_SDB and the second surface of the isolation structure SDB may be an upper surface US_SDB. At least a portion of the lower surface LS_SDB of the isolation structure SDB may be located inside the first and second active patterns AP1 and AP2. For example, with respect to the substrate 100, the level in the third direction D3 of the lower surface LS_SDB of the isolation structure SDB may be located between the upper surfaces and the lower surfaces of the first and second active patterns AP1 and AP2.

As will be described later, after sequentially forming the first interlayer insulating layer 110, the gate pattern GE, the gate capping pattern GP, and the second interlayer insulating layer 120 in the third direction D3, a third recess RS3 may be formed through a pair of gate patterns GE located on the outer side of the logic cell LC in the third direction D3, and an insulating material may be filled inside the third recess RS3 to form the isolation structure SDB.

Accordingly, the isolation structure SDB may penetrate the first and second interlayer insulating layers 110 and 120, the gate capping pattern GP, the gate pattern GE, the first and second channel patterns CH1 and CH2, or a combination thereof, in the third direction D3.

In one example, the gate capping pattern GP, the gate pattern GE, and the first and second channel patterns CH1 and CH2 located around the third recess RS3 are completely removed during formation of the third recess RS3 and the isolation structure SDB may penetrate the first and second interlayer insulating layers 110 and 120, and the lower surface of the isolation structure SDB may be located inside the first and second active patterns AP1 and AP2.

In another example, the gate capping pattern GP, the gate pattern GE, and the first and second channel patterns CH1 and CH2 located around the third recess RS3 are not completely removed during formation of the third recess RS3 and the isolation structure SDB may penetrate the first and second interlayer insulating layers 110 and 120, the gate capping pattern GP, the gate pattern GE, and the first and second channel patterns CH1 and CH2, and the lower surface LS_SDB of the isolation structure SDB may be located inside the first and second active patterns AP1 and AP2. In this case, next to the isolation structure SDB in the second direction D2, some structures of the gate capping pattern GP, the gate pattern GE, and the first and second channel patterns CH1 and CH2 that were not removed during the formation of the third recess RS3 may remain. In particular, when the gate insulating layer GI is interposed between the first to third portions PO1 to PO3 of the gate pattern GE and the first and second source/drain patterns SD1 and SD2, a portion of the gate insulator GI may remain next to the isolation structure SDB in the second direction D2, for example, between the isolation structure SDB and the first and second source/drain patterns SD1 and SD2.

The isolation structure SDB may extend in the third direction D3 and overlap the first and second source/drain patterns SD1 and SD2 and the gate pattern GP in the second direction D2. In one example, the isolation structure SDB may extend in the third direction D3 from the upper surface of the second interlayer insulating layer 120 to the interior of the first and second active patterns AP1 and AP2. For example, relative to the substrate 100, the upper surface US_SDB of the isolation structure SDB may be located substantially at the same level in the third direction D3 as the upper surface of the second interlayer insulating layer 120. For example, the upper surface US_SDB of the isolation structure SDB may penetrate the lower surface LS_100 of the second interlayer insulating layer 120 and contact the lower surface LS_130 of the third interlayer insulating layer 130 which will be described below.

As the isolation structure SDB extends in the first direction D1, at least a portion of the lower surface LS_SDB of the isolation structure SDB may pass inside the first and second active patterns AP1 and AP2, and a remaining portion may pass through the substrate 100 or the device isolation layer ST. Thus, the lower surface LS_SDB of the isolation structure SDB crosses the first and second active patterns AP1 and AP2 in the first direction D1, and the isolation structure SDB may divide the first and second active patterns AP1 and AP2 into a plurality of portions spaced apart in the second direction.

Accordingly, the isolation structure SDB may define one logic cell LC and distinguish one logic cell LC from another logic cell LC. For example, the isolation structure SDB may separate the first and second active regions PR and NR of the logic cell LC from the active regions of neighboring logic cells.

The length of the isolation structure SDB in the second direction D2 may be constant until the isolation structure SDB passes through the first and second interlayer insulating layers 110 and 120, the gate capping pattern GP, the gate pattern GE, or the first and second channel patterns CH1 and CH2 in the third direction D3. The length of the isolation structure SDB in the second direction D2 may be decreased as it goes downwardly in the third direction D3 within the first and second active patterns AP1 and AP2. Here, the length of the isolation structure SDB in the second direction D2 means the width of the isolation structure SDB, which may be the shortest length in the second direction D2 from one sidewall of the isolation structure SDB to the other sidewall.

Accordingly, in a cross-section taken along the second direction D2 and the third direction D3 perpendicular to the first direction D1 (i.e., normal to the first direction), that is, in FIGS. 2 and 3, the surface where the isolation structure SDB is in contact with the first and second active patterns AP1 and AP2, that is, the lower surface LS_SDB of the isolation structure SDB, may have a shape that is convex downwardly toward the first and second active patterns AP1 and AP2, for example, a sharp shape, a rounded shape, or a flat shape.

The isolation structure SDB includes insulating structures DBF and DBO, and an insulating liner DBL surrounding the insulating structures DBF and DBO. The insulating structures DBF and DBO may include a first portion and a second portion having different content (atom %) of oxygen (O), carbon (C), or both oxygen (O) and carbon (C). In one example, the insulating structures DBF and DBO may include at least two insulating patterns DBF stacked in the third direction D3, and an interfacial layer DBO located between the insulating patterns DBF. The insulating patterns DBF and the interfacial layer DBO may have different content (atom %) of oxygen (O), carbon (C), or both oxygen (O) and carbon (C). That is, the first portion of the insulating structures DBF and DBO may be the insulating patterns DBF and the second portion of the insulating structures DBF and DBO may be the interfacial layer DBO.

As described above, when the gate pattern GE is removed, the first and second channel patterns CH1 and CH2 and the first and second active patterns AP1 and AP2 are etched to a certain depth from the upper surface to form the third recess RS3, and then the third recess RS3 is filled with an insulating material by using a gap fill process to form the isolation structure SDB. Due to various structures and difference in material surfaces of the gate pattern GE and the first and second channel patterns CH1 and CH2 that are in contact with the third recess RS3, the insulating material may not grow uniformly, resulting in a seam, and the seam may be deformed into a void by widening in a subsequent process (for example, a CMP and a wet process)

Seams and voids may cause failures, such as separation of the isolation structure during subsequent processing.

However, as will be described later, when the isolation structure SDB is formed by filling the third recess RS3 with the insulating material, it is possible to form the isolation structure SDB without voids or seams when a cycle process of depositing a fluidized layer and curing the fluidized layer is repeated. In this case, during the process of curing the fluidized layer, oxygen (O) or carbon (C) may be generated, resulting in the formation of the interfacial layer DBO that is rich in oxygen (O), carbon (C), or both oxygen (O) and carbon (C) between the insulating patterns DBF. Thus, the insulating structures DBF and DBO may include at least two insulating patterns DBF stacked in the third direction D3, and the interfacial layer DBO located between the insulating patterns DBF. The interfacial layer DBO may have a higher content (% atoms) of oxygen (O), carbon (C), or both oxygen (O) and carbon (C) than the insulating patterns DBF.

In one example, the isolation structure SDB without seams and voids may be described as not having a void in the range of 2 nm to 10 nm. The isolation structure SDB may have a void greater than 0 nm and less than 2 nm and still be considered to be without seams and voids, but the isolation structure SDB may also have no void greater than 0 nm and less than 2 nm.

However, the oxygen (O) or carbon (C) included in the interfacial layer DBO may be diffused during subsequent processing and cause adverse effects on the first and second channel patterns CH1 and CH2. The insulating liner DBL may surround the insulating structures DBF and DBO to prevent oxygen (O) or carbon (C) included in the interfacial layer DBO from being diffused into the first and second channel patterns CH1 and CH2 during subsequent processing.

The insulating liner DBL may conformably cover the inner wall of the third recess RS3. In one example, the insulating liner DBL may have a cross-sectional shape that is U-shaped along the profile of the third recess RS3.

The insulating liner DBL may extend in the third direction D3 to be in contact with the first and second interlayer insulating layers 110 and 120, the gate capping pattern GP, the gate pattern GE, the gate spacers GS, the first and second channel patterns CH1 and CH2, the first and second active patterns AP1 and AP2, or combinations thereof. In particular, the insulating liner DBL may conformably cover the inner wall of the lower surface of the third recess RS3 to be in contact with the first and second active patterns AP1 and AP2.

The thickness of the insulating liner DBL, that is, the shortest length in the second direction D2, may be 2 nm or more, 3 nm or more, or 4 nm or more, and may be 5 nm or less, 4 nm or less, or 3 nm or less, and may be, for example, 2 nm to 5 nm, in order to prevent oxygen (O) or carbon (C) included in the interfacial layer DBO from being diffused into the first and second channel patterns CH1 and CH2 during a subsequent process.

In one example, the insulating liner DBL may be formed of and/or include an insulating material that does not include oxygen (O) to prevent oxygen (O) or carbon (C) included in the interfacial layer DBO from being diffused into the first and second channel patterns CH1 and CH2 during subsequent processing, and may include, for example, silicon nitride (SiN), silicon carbon nitride (SiCN), or a combination thereof.

The insulating structures DBF and DBO may fill the inner region of the third recess RS3 left after the insulating liner DBL is formed. For example, the insulating liner DBL may surround the insulating structures DBF and DBO. The insulating liner DBL may be located between the insulating structures DBF and DBO and the first and second interlayer insulating layers 110 and 120, the first and second source/drain patterns SD1 and SD2, the gate pattern GE, the first and second channel patterns CH1 and CH2, the first and second active patterns AP1 and AP2, or any combination thereof.

The insulating structures DBF and DBO include at least two insulating patterns DBF stacked in the third direction D3, and the interfacial layer DBO located between the insulating patterns DBF. For example, the insulating structures DBF and DBO may have a multi-layered insulating layer structure including at least two insulating patterns DBF stacked in the third direction D3. In one example, the insulating structures DBF and DBO may include 2 or more, 3 or more, 4 or more, 5 or more, 6 or more, 7 or more, 8 or more, 9 or more, 10 or more, 11 or more, 12 or more, 13 or more, 14 or more, 15 or more, 16 or more, 17 or more, 18 or more, 19 or more insulating patterns DBF, or 20 or more, and may include 20 or fewer, 19 or fewer, 18 or fewer, 17 or fewer, 16 or fewer, 15 or fewer, 14 or fewer, 13 or fewer, 12 or fewer, 11 or fewer, 10 or fewer, 9 or fewer, 8 or fewer, 7 or fewer, 6 or fewer, 5 or fewer, 4 or fewer, or 3 or fewer insulating patterns DBF.

The insulating structures DBF and DBO may include 1 or more, 2 or more, 3 or more, 4 or more, 5 or more, 6 or more, 7 or more, 8 or more, 9 or more, 10 or more, 11 or more, 12 or more, 13 or more, 14 or more, 15 or more, 16 or more, 17 or more, 18 or more interfacial layers DBO, or 19 or more, and may include 19 or fewer, 18 or fewer, 17 or fewer, 16 or fewer, 15 or fewer, 14 or fewer, 13 or fewer, 12 or fewer, 11 or fewer, 10 or fewer, 9 or fewer, 8 or fewer, 7 or fewer, 6 or fewer, 5 or fewer, 4 or fewer, 3 or fewer, or 2 or fewer interfacial layers DBO.

The length of one insulating pattern DBF in the third direction D3, that is, the height of the insulating pattern DBF, may be 1 nm or more, 10 nm or more, 50 nm or more, or 100 nm or more, or 150 nm or less, 100 nm or less, 50 nm or less, or 10 nm or less.

In one example, the insulating patterns DBF and the interfacial layer DBO may be formed of and/or include silicon nitride (SiN), silicon nitride oxide (SiON), silicon carbide (SiCN), or a combination thereof.

In one example, the insulating patterns DBFs may be formed of and/or include silicon (Si) and nitrogen (N), and may not include oxygen (O), carbon (C), or both oxygen (O) and carbon (C). In another example, the insulating patterns DBFs include silicon (Si) and nitrogen (N) and may further include oxygen (O), carbon (C), or both oxygen (O) and carbon (C). The interfacial layer DBO includes silicon (Si) and nitrogen (N), and may further include oxygen (O), carbon (C), or both oxygen (O) and carbon (C).

The insulating pattern DBF and the interfacial layer DBO may have different contents (at %) of oxygen (O), carbon (C), or both oxygen (O) and carbon (C), for example, the interfacial layer DBO may have a greater content (at %) of oxygen (O), carbon (C), or both oxygen (O) and carbon (C) compared to the insulating pattern DBF.

Herein the content of oxygen (O), carbon (C), or both oxygen (O) and carbon (C) in the insulating pattern DBF is atom % of oxygen (O), carbon (C), or both oxygen (O) and carbon (C) based on the total at % of one insulating pattern DBF, and the content of oxygen (O), carbon (C), or both oxygen (O) and carbon (C) in the interfacial layer DBO may be atom % of oxygen (O), carbon (C), or both oxygen (O) and carbon (C) based on the total at % of the interfacial layer DBO.

In one example, the insulating pattern DBF may include, based on the total at % of the insulating pattern DBF, from 30 at % to 60 at % of silicon (Si), from 30 at % to 60 at % of nitrogen (N), from 0 at % to 5 at % or more of oxygen (O), and from 0 at % to 50 at % of carbon (C), and the insulating pattern DBF may include, for example, 30 at % to 60 at % of silicon (Si), 30 at % to 60 at % of nitrogen (N), 0 at % to 5 at % or more of oxygen (O), and 0 at % to 50 at % or more of carbon (C) based on the total at % of the insulating pattern.

The interfacial layer DBO may include from 20 at % to 60 at % of silicon (Si), from 30 at % to 60 at % of nitrogen (N), from 0 at % to greater than 20 at % of oxygen (O), and from greater than 0 at % to 50 at % of carbon (C), based on the total at % of the interfacial layer DBO, and the interfacial layer DBO may include, for example, 20 at % to 60 at % of silicon (Si), 30 at % to 60 at % of nitrogen (N), greater than 5 at % to 20 at % of oxygen (O), and greater than 0 at % to 50 at % of carbon (C), based on the total at % of the interfacial layer DBO. For example, the content (at %) of oxygen (O) in the interfacial layer DBO may be greater than the content (at %) of oxygen (O) in the insulating patterns DBF.

The active contact AC may penetrate the first and second interlayer insulating layers 110 and 120 and be electrically connected to the first and second source/drain patterns SD1 and SD2, respectively. In one example, a pair of active contacts AC may be disposed between gate patterns GE. In a plan view, the active contact AC may have a bar shape extending in the first direction D1.

As used herein, items described as being “electrically connected” are configured such that an electrical signal can be passed from one item to the other. Therefore, a passive electrically conductive component (e.g., a wire, pad, internal electrical line, etc.) physically connected to a passive electrically insulative component (e.g., a prepreg layer of a printed circuit board, an electrically insulative adhesive connecting two devices, an electrically insulative underfill or mold layer, etc.) is not electrically connected to that component.

Silicide patterns SC may be interposed between the active contact AC and the first source/drain pattern SD1 and between the active contact AC and the second source/drain pattern SD2, respectively. The active contact AC may be electrically connected to the first and second source/drain patterns SD1 and SD2 via the silicide pattern SC. The silicide pattern SC may be formed of and/or include a metal-silicide, which may include, for example, titanium-silicide, tantalum-silicide, tungsten-silicide, nickel-silicide, cobalt-silicide, or a combination thereof.

The gate contact GC may penetrate through the second interlayer insulating layer 120 and the gate capping pattern GP to be electrically connected with the gate pattern GE. In one example, referring to FIG. 3, the top of each of the active contacts AC adjacent to the gate contact GC may be removed and the resulting space filled with an upper insulating pattern UIP. This prevents a process defect in which the gate contact GC contacts an adjacent active contact 10 AC, causing a short.

Each of the active contact AC and the gate contact GC may include a conductive pattern FM and a barrier pattern BM surrounding the conductive pattern FM. For example, the conductive pattern FM may be formed of and/or include aluminum, copper, tungsten, molybdenum, or a combination thereof. The barrier pattern BM may cover the sidewalls and lower surface of the conductive pattern FM. The barrier pattern BM may include a metal film or a metal nitride film. The metal film may be formed of and/or include titanium, tantalum, tungsten, nickel, cobalt, platinum, or a combination thereof. The metal nitride film may be formed of and/or include titanium nitride (TiN), tantalum nitride (TaN), tungsten nitride (WN), nickel nitride (NiN), cobalt nitride (CON), platinum nitride (PtN), or a combination thereof.

The third interlayer insulating layer 130 is located on the active contact AC and the gate contact GC, and may cover the active contact AC and the gate contact GC.

A first metal layer M1 may be disposed within the third interlayer insulating layer 130. The first metal layer M1 may include first power wires M1_R, first wires M1_I, and first vias V1. The first via VI1 may be disposed below the first power wires M1_R and the first wires M1_I.

Each of the first power wires M1_R may extend in the second direction D2 across the logic cell LC. Each of the first power wires M1_R may be a power wire. For example, a drain voltage VDD or a source voltage VSS may be applied to the first power wire M1_R.

Referring to FIG. 1, a logic cell LC may be defined with a first cell boundary CB1 extending in the second direction D2. In the logic cell LC, a second cell boundary CB2 extending in the second direction D2 may be defined opposite the first cell boundary CB1. The first power wire M1_R may be disposed on the first cell boundary CB1 to which a drain voltage VDD, that is, a power voltage, is applied. The first power wire M1_R, to which the drain voltage VDD is applied, may extend in the second direction D2 along the first cell boundary CB1. On the second cell boundary CB2, the first power wire M1_R may be arranged to which the source voltage VSS, that is, the ground voltage, is applied. The first power wire M1_R, to which the source voltage VSS is applied, may extend in the second direction D2 along the second cell boundary CB2.

The first wires M1_I may be disposed along the first direction D1 between the first power wire M1_R to which the drain voltage VDD is applied and the first power wire M1_R to which the source voltage VSS is applied. Each of the first wires M1_I may have a line or bar shape extending in the second direction D2. The first wires M1_I may be arranged along the first direction D1 with a second pitch P2. The second pitch P2 may be smaller than the first pitch P1.

The first via VI1 may be disposed below the first power wires M1_R and the first wires M1_I. The first vias VI1 may be interposed between the active contact AC and the first power wires M1_R and the first wires M1_I, respectively. Further, the first vias VI1 may be interposed between the gate contact GC and the first wires M1_I, respectively.

The fourth interlayer insulating layer 140 is located on the third interlayer insulating layer 130 and may cover the third interlayer insulating layer 130.

The second metal layer M2 may be disposed within the fourth interlayer insulating layer 140. The second metal layer M2 may include second wires M2_1. Each of the second wires M2_I may have a line or bar shape extending in the first direction D1. For example, the second wires M2_I May extend parallel to each other in the first direction D1. From a plan view, the second wires M2_I may be parallel to the gate pattern GE. The second wires M2_I may be arranged along the second direction D2 with a third pitch P3. The third pitch P3 may be smaller than the first pitch P1. The third pitch P3 may be larger than the second pitch P2.

The second metal layer M2 may further include second vias VI2. The second vias VI2 may be placed below the second wires M2_I. The second vias VI2 may be interposed between the first power wires M1_R and the first wires M1_I and the second wires M2_I, respectively.

The first power wires M1_R and the first wires M1_I of the first metal layer M1 and the second wires M2_I of the second metal layer M2 may include the same or different conductive materials. For example, the first power wires M1_R, the first wires M1_I, and the second wires M2_I may be formed of and/or include aluminum, copper, tungsten, molybdenum, cobalt, or a combination thereof.

Although not shown, in some embodiments, there may be additional top metal layers (for example, M3, M4, and M5) stacked on top of the fourth interlayer insulating layer 140. Each of the stacked top metal layers may include routing wires.

Hereinafter, a semiconductor device according to another embodiment will be described with reference to FIG. 7. FIG. 7 is a cross-sectional view corresponding to FIG. 6 for another embodiment.

The embodiment illustrated in FIG. 7 has many elements that are substantially the same as those described in relation to the embodiments illustrated in FIGS. 1 to 6, and therefore FIG. 7 will be described mainly with respect to the differences. Description that may otherwise be duplicative with the previous description may be omitted with the understanding that the previous description is applicable.

In FIG. 6, it is illustrated that the isolation structure SDB includes at least two insulating patterns DBFs stacked in the third direction D3, the interfacial layer DBO located between the insulating patterns DBFs, and an insulating liner DBL surrounding the insulating patterns DBFs.

In FIG. 7, it is illustrated that an isolation structure SDB includes at least two insulating patterns DBF stacked in the third direction D3, an interfacial layer DBO located between the insulating patterns DBF, a first insulating liner DBL surrounding the insulating patterns DBF, and an insulating spacer DBS located between the insulating patterns DBF and the insulating liner DBL.

In the isolation structure SDB, the insulating spacer DBS may fill a lower end portion of a third recess RS3 in which the insulating liner DBL is formed and cover the inner wall.

As will be described later, the insulating spacer DBS is conformally deposited (for example, atomic layer deposition (ADL)) inside the third recess RS3 where the insulating liner DBL is formed, and then the insulating spacers DBS located on the upper portion of the third recesses RS3 are removed by a chamfering process to increase the linewidth of the third recess RS3, thereby facilitating the progress of the subsequent formation of the insulating patterns DBF.

Accordingly, the insulating spacer DBS may have a lower end portion DBS_L located at the bottom of the isolation structure SDB and sidewall portions DBS_S extending in the third direction D3 from the lower end portion DBS_L. The lower end portion DBS_L of the insulating spacer DBS may fill the lower end portion of the third recess RS3 where the insulating liner DBL is formed. For example, the lower end portion DBS_L of the insulating spacer DBS may be in contact with a lower surface (LS_SDB) of the isolation structure SDB and may be located inside the first and second active patterns AP1 and AP2.

The sidewall portions DBS_S of the insulating spacers DBS extend in the third direction D3 along the insulating liner DBL. The sidewall portions DBS_S of the insulating spacer DBS may be located between the insulating structures DBF and DBO and the insulating liner DBL.

As described above, as the insulating spacer DBS is manufactured by conformal deposition of an insulating material film followed by chamfering, the length, that is, thickness, of the sidewall portions DBS_S of the insulating spacer DBS in the second direction D2 may decrease toward the third direction D3. Also, the sidewall portions DBS_S of the insulating spacer DBS may not extend to the top of the third recess RS3. For example, at the top of the third direction D3 of the isolation structure SDB, the insulating spacer DBS may not be located between the insulating liner DBL and the insulating structures DBF and DBO. Accordingly, the overall shape of the upper surface of the insulating spacer DBS, that is, the surface that is in contact with the insulating patterns DBF, may be V-shaped.

Furthermore, the length in the second direction D2, that is, thickness, of the side wall portions DBS_S of the insulating spacer DBS may be greater than the length in the second direction D2 of the insulating liner DBL and less than length in the second direction D2 of the isolation structure SDB, that is, half the linewidth of the third recess RS3.

The thickness of the sidewall portions DBS_S of the insulating spacers DBS may be greater than the length of the second direction D2 of the insulating liner DBL to fill the lower end portion of the third recess RS3 and help the subsequent process of forming the insulating patterns DBF. In addition, the thickness of the sidewall portions DBS_S of the insulating spacer DBS may be be less than half of the length in the second direction D2 of the isolation structure SDB so that a hollow space (e.g., not containing the material of the insulating spacer DBS) remains between the sidewall portions DBS_S of the insulating spacer DBS, and the insulating patterns DBF may be located in the hollow space.

In one example, the insulating spacer DBS may be formed of and/or include an insulating material having the better gap fill characteristic than the insulating liner DBL, such as silicon nitride (SiN), silicon nitride oxide (SiON), silicon carbide (SiCN), or a combination thereof.

The insulating structures DBF and DBO may fill the inner area of the remaining third recess RS3 after the insulating spacer DBS is formed. The insulating pattern DBF of the insulating structures DBF and DBO may be located on the lower end portion DBS_L of the insulating spacer DBS, and the insulating pattern DBF may be located between the sidewall portions DBS_S of the insulating spacer DBS. For example, the insulating spacer DBS may surround at least a portion of the insulating structures DBF and DBO.

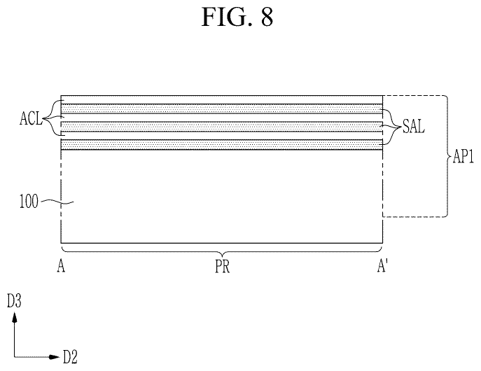

FIGS. 8 to 33 are cross-sectional views of various states of a partially manufactured semiconductor devise illustrating a method of manufacturing the semiconductor device according to an embodiment.

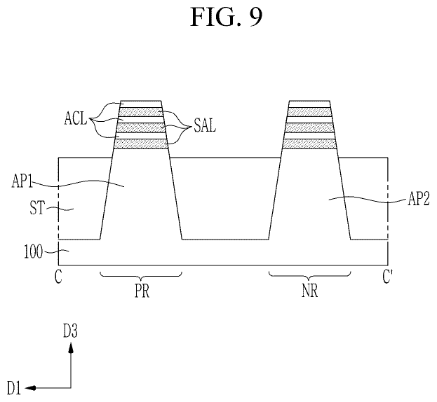

FIG. 8 is a cross-sectional view taken along lines A-A′ in FIG. 1. In this case, the cross section taken along line B-B′ in FIG. 1 may be the same as FIG. 8, so it is omitted. FIG. 9 is a cross-sectional view taken along line C-C′ in FIG. 1. In this case, the cross-sectional view taken along lines D-D′ in FIG. 1 may be the same as FIG. 9, so it is omitted.

Referring to FIGS. 8 and 9, a substrate 100 is formed that includes a PMOSFET region PR and an NMOSFET region NR.

First, alternately stacked sacrificial layers SALs and active layers ACLs are formed on the substrate 100. The sacrificial layers SALs may be formed of and/or include silicon (Si), germanium (Ge), or silicon-germanium (SiGe), and active layers ACLs may be formed of and/or include silicon (Si), germanium (Ge), or silicon-germanium (SiGe). For example, the sacrificial layers SALs may be formed of and/or include silicon-germanium (SiGe), and the active layers ACLs may be formed of and/or include silicon (Si). The concentration of germanium (Ge) in each of the sacrificial layers SALs may be from 10 at % to 30 at %.

Mask patterns may be formed on the PMOSFET regions PR and NMOSFET regions NR of the substrate 100, respectively. The mask pattern may have a line shape or a bar shape extending in the second direction D2.

By performing a patterning process on the mask patterns with an etch mask, trenches defining a first active pattern AP1 and a second active pattern AP2 may be formed. Accordingly, in the logic cell region CER, a first active pattern AP1 and a second active pattern AP2 may be formed in the PMOSFET region PR and the NMOSFET region NR, respectively.

Each of the first active pattern AP1 and the second active pattern AP2 may include the alternately stacked sacrificial layers SALs and active layers ACLs on the upper portion thereof.

Next, a device isolation layer ST is formed that fills the trench on the substrate 100.

In one example, the device isolation layer ST may be formed to cover both the first active pattern AP1 and the second active pattern AP2.

The device isolation layer ST may be formed of and/or include an insulating material, such as a silicon oxide film.

Next, the sacrificial layers SALs in the upper portions of the first active pattern AP1 and the second active pattern AP2 are exposed.

In one example, the mask patterns are formed on the first active pattern AP1 and second active pattern AP2 of the logic cell region CER, and a patterning process is performed with the mask patterns as an etch mask to recess the device isolation layer ST until the sacrificial layers SALs are exposed.

Thereby, the upper portion of each of the first active pattern AP1 and the second active pattern AP2 may be exposed on the device isolation layer ST. For example, the upper portion of each of the first active pattern AP1 and the 10 second active pattern AP2 may protrude from the device isolation layer ST in in the third direction D3.

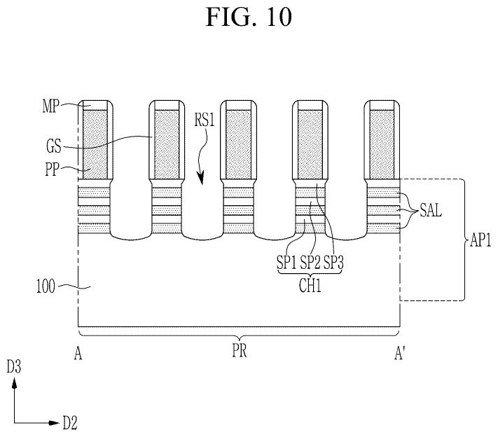

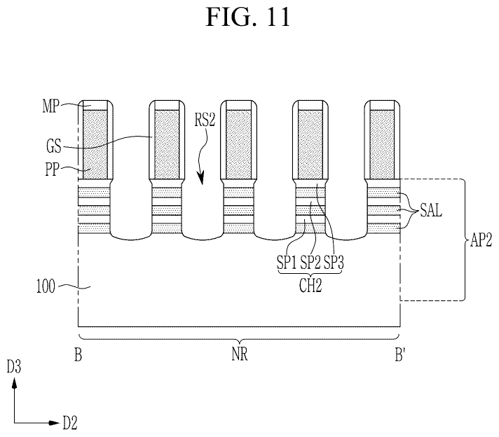

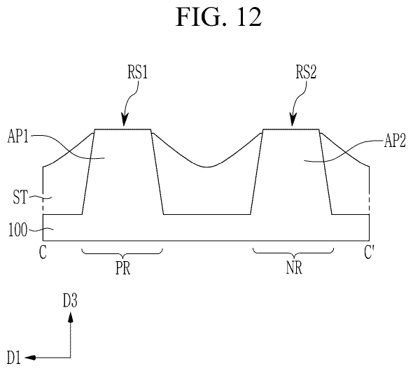

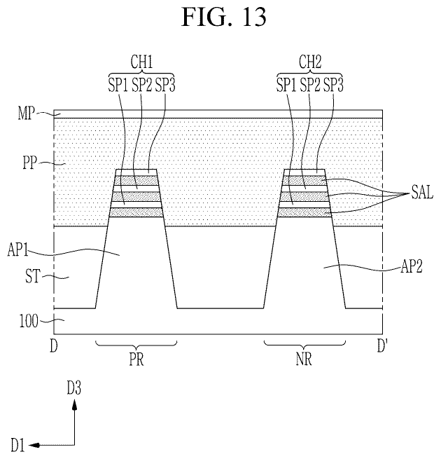

FIG. 10 is a cross-sectional view taken along line A-A′ in FIG. 1. FIG. 11 is a cross-sectional view taken along line B-B′ in FIG. 1. FIG. 12 is a cross-sectional view taken along line C-C′ in FIG. 1. FIG. 13 is a cross-sectional view taken along lines D-D′ in FIG. 1.

Referring to FIGS. 10 to 13, a sacrificial pattern PP is formed across the first active pattern AP1 and the second active pattern AP2, and first recesses RS1 and second recesses RS2 are formed on the upper portion of the first active pattern AP1 and the second active pattern AP2, respectively.

First, a sacrificial pattern PP may be formed by forming a sacrificial layer on the front side of the substrate 100, forming a hard mask pattern MP on the sacrificial layer, and patterning the sacrificial layer with the hard mask pattern MP as the etch mask.

In one example, the sacrificial pattern PP may be formed in a line shape or a bar shape extending in the first direction D1. The sacrificial pattern PP may be arranged along the second direction D2 with a predetermined pitch. The sacrificial layer may be formed of and/or include polysilicon.

Next, a pair of gate spacers GS may be formed on both sidewalls of each sacrificial pattern PP.

In one example, a gate spacer layer may be conformally formed on the front side of the substrate 100, and the gate spacer layer may be anisotropically etched to form the gate spacer GS.

In one example, the gate spacer layer may be formed of and/or include SiCN, SiCON, SIN, or a combination thereof. Additionally, the gate spacer layer may be formed of and/or include a multi-layer including SiCN, SiCON, SIN, or a combination thereof.

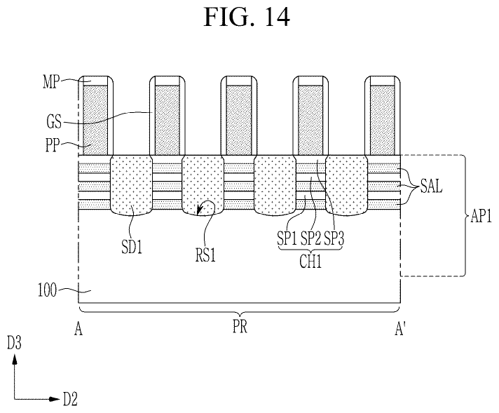

Next, first recesses RS1 may be formed on the upper portion of the first active pattern AP1, and second recesses RS2 may be formed on the upper portion of the second active pattern AP2. During the formation of the first and second recesses RS1 and RS2, the upper surface of the device isolation layer ST on opposite sides of each of the first and second active patterns AP1 and AP2 may be recessed (see FIG. 14).

In one example, the first recesses RS1 may be formed by etching the upper portion of the first active pattern AP1 by using the hard mask pattern MP and the gate spacer GS as an etch mask. The first recess RS1 may be formed between a pair of sacrificial patterns PP. The second recesses RS2 on the upper portion of the second active pattern AP2 may be formed in the same manner as the first recesses RS1.

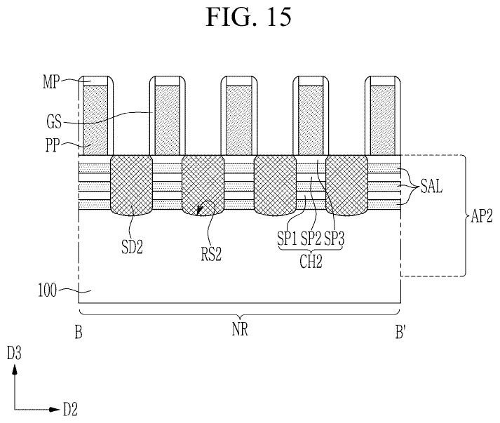

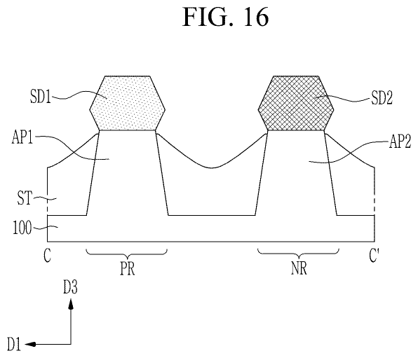

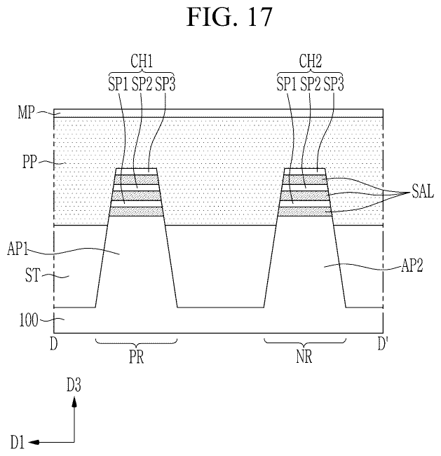

FIG. 14 is a cross-sectional view taken along lines A-A′ in FIG. 1. FIG. 15 is a cross-sectional view taken along line B-B′ in FIG. 1. FIG. 16 is a cross-sectional view taken along line C-C′ in FIG. 1. FIG. 17 is a cross-sectional view taken along line D-D′ in FIG. 1.

Referring to FIGS. 14 to 17, a first source/drain pattern SD1 is formed within the first recess RS1, and a second source/drain pattern SD2 is formed within the second recess RS2.

In one example, a first semiconductor layer may be formed by performing a first selective epitaxial growth SEG process with the inner wall of the first recess RS1 as a seed layer. The first semiconductor layer may be grown by using the first to third semiconductor patterns SP1, SP2, and SP3 and the first active pattern AP1 exposed by the first recess RS1 as seeds. In one example, the first SEG process may include a Chemical Vapor Deposition (CVD) process or a Molecular Beam Epitaxy (MBE) process.

The first semiconductor layer may be formed of and/or include a semiconductor element (for example, SiGe) having a lattice constant greater than a lattice constant of the semiconductor element of the first active pattern AP1. The first semiconductor layer may include a relatively low concentration of germanium (Ge). In another example, the first semiconductor layer may include only silicon (Si), excluding germanium (Ge). The concentration of germanium (Ge) in the first semiconductor layer may be from 0 at % to 10 at %.

By performing the second SEG process on the first semiconductor layer, a second semiconductor layer may be formed. The second semiconductor layer may be formed to completely fill the first recess RS1. The second semiconductor layer may include a relatively high concentration of germanium (Ge). In one example, the concentration of germanium (Ge) in the second semiconductor layer may be from 30 at % to 70 at %.

The first semiconductor layer and the second semiconductor layer may include a first source/drain pattern SD1. During the first and second SEG processes, impurities may be injected in-situ. In another example, impurities may be injected into the first source/drain pattern SD1 after the first source/drain pattern SD1 is formed. The first source/drain pattern SD1 may be doped to have a first conductive type (for example, p-type).

Next, the second source/drain pattern SD2 may be formed by performing a Selective Epitaxial Growth (SEG) process with the inner wall of the second recess RS2 as the seed layer. In one example, the second source/drain pattern SD2 may be grown with the first to third semiconductor patterns SP1, SP2, and SP3 and the second active pattern AP2 exposed as the second recess RS2.

In one example, the second source/drain pattern SD2 may include the same semiconductor element (for example, Si) as the second active pattern AP2. The second source/drain pattern SD2 may be doped to have a second conductive type (for example, n-type).

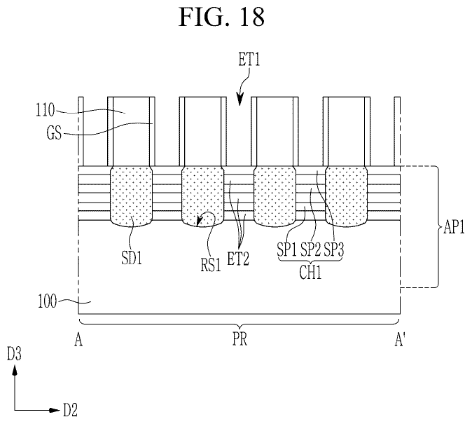

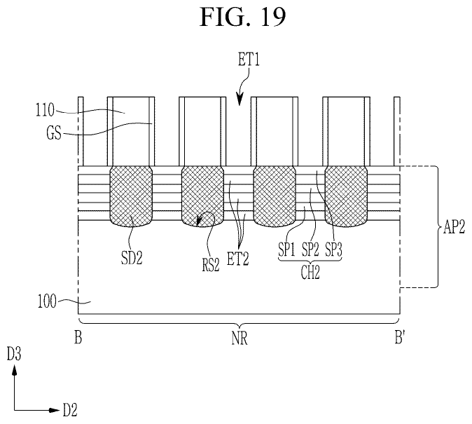

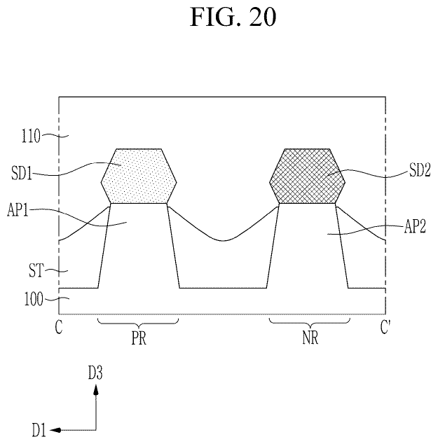

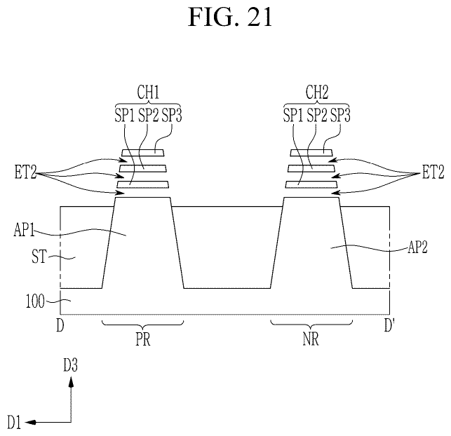

FIG. 18 is a cross-sectional view taken along lines A-A′ in FIG. 1. FIG. 19 is a cross-sectional view taken along line B-B′ in FIG. 1. FIG. 20 is a cross-sectional view taken along line C-C′ in FIG. 1. FIG. 21 is a cross-sectional view taken along lines D-D′ in FIG. 1.

Referring to FIGS. 18 to 21, after forming a first interlayer insulating layer 110, the sacrificial pattern PP is removed and the exposed sacrificial layers SALs are removed.

First, a first interlayer insulating layer 110 covering the first and second source/drain patterns SD1 and SD2, the hard mask pattern MP, and the gate spacer GS is formed. In one example, the first interlayer insulating layer 110 may include a silicon oxide film.

Next, the first interlayer insulating layer 110 may be planarized until the upper surface of the sacrificial pattern PP is exposed. Planarization of the first interlayer insulating layer 110 may be performed by using an etch back or Chemical Mechanical Polishing (CMP) process. During the planarization process, all hard mask patterns MP may be removed. As a result, the upper surface of the first interlayer insulating layer 110 may be located at substantially the same level as the upper surface of the sacrificial pattern PP and the upper surface of the gate spacer GS.

The exposed sacrificial pattern PP may be selectively removed. As the sacrificial pattern PP is removed, first empty spaces ET1 may be formed to expose the first and second active patterns AP1 and AP2.

On the other hand, some of the sacrificial patterns PPs may not be removed. For example, a sacrificial pattern PP located on a cell boundary May not be removed. For example, by forming a mask pattern on the sacrificial pattern PP that should not be removed, the sacrificial pattern PP may be left without being removed. With the removal of the sacrificial pattern PP, the sacrificial layer SAL of each of the first and second active patterns AP1 and AP2 may be exposed through the first empty space ET1.

Next, the exposed sacrificial layers SALs may be selectively removed through the first space ET1.

In one example, an etch process that selectively etches the sacrificial layers SALs may be performed to remove only the sacrificial layers SALs while leaving the first to third semiconductor patterns SP1, SP2, and SP3. The etch process may have a high etch rate for silicon-germanium with a relatively high germanium concentration. For example, the etch process may have a high etch rate for silicon-germanium with a germanium concentration greater than 10 at %.

During the etch process, the sacrificial layers SALs on the PMOSFET region PR and the NMOSFET region NR may be removed. The etch process may be a wet etch. The etching material used in the etch process may quickly remove the sacrificial layer SAL with a relatively high germanium concentration.

By selectively removing the sacrificial layers SALs, only the first to third semiconductor patterns SP1, SP2, and SP3 may remain on each of the first and second active patterns AP1 and AP2. Second empty spaces ET2 may be formed through the regions where the sacrificial layers SALs have been removed. The second empty spaces ET2 may be located between the first to third semiconductor patterns SP1, SP2, and SP3.

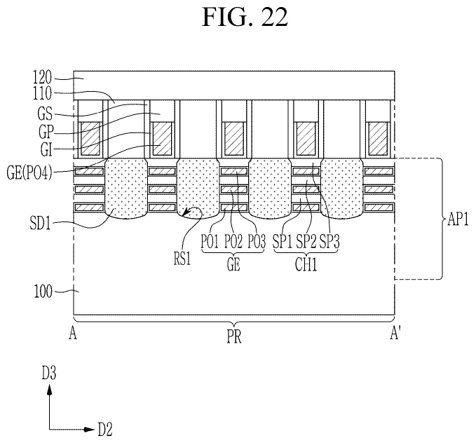

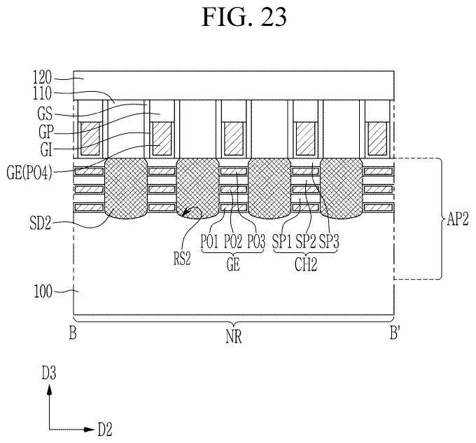

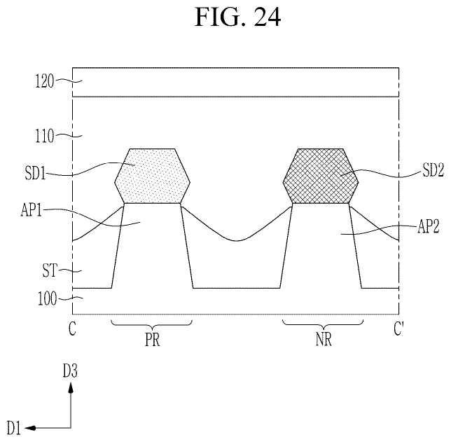

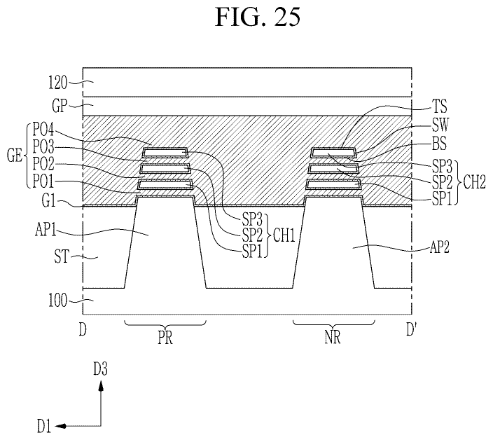

FIG. 22 is a cross-sectional view taken along lines A-A′ in FIG. 1. FIG. 23 is a cross-sectional view taken along line B-B′ in FIG. 1. FIG. 24 is a cross-sectional view taken along line C-C′ in FIG. 1. FIG. 25 is a cross-sectional view taken along lines D-D′ in FIG. 1.

Referring to FIGS. 22 to 25, a gate pattern GE is formed within the first and second empty spaces ET1 and ET2.

First, a gate insulating layer GI is conformally formed within the first and second empty spaces ET1 and ET2. A gate pattern GE may then be formed on the gate insulating layer GI. The gate pattern GE may be formed to fill the first and second empty spaces ET1 and ET2.

In one example, the gate pattern GE may include first to third portions PO1, PO2, and PO3 that fill the second empty space ET2. The gate pattern GE may further include a fourth portion PO4 that fills the first empty space ET1.

Next, a gate capping pattern GP may be formed that covers the gate pattern GE on the gate pattern GE. Additionally, a second interlayer insulating layer 120 may be formed on the first interlayer insulating layer 110. The second 10 interlayer insulating layer 120 may include a silicon oxide film.

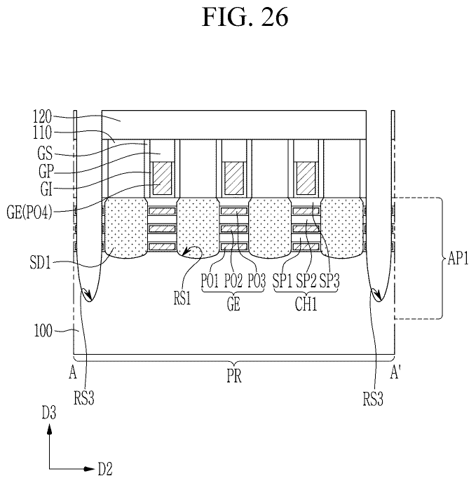

FIG. 26 is a cross-sectional view taken along lines A-A′ in FIG. 1. In this case, a cross-sectional view taken along line B-B′ of FIG. 1 may be substantially the same as FIG. 26, so it is omitted. Also, in the process described in FIG. 26, a cross-sectional view taken along line C-C′ in FIG. 1 is omitted as it may be substantially unchanged from FIG. 24. Furthermore, in the process described in FIG. 26, a cross-sectional view taken along lines D-D′ of FIG. 1 is omitted as it may be substantially unchanged from FIG. 25.

Referring to FIG. 26, third recesses RS3 are formed through each of a pair of gate patterns GE located at opposite ends of the logic cell LC.

In one example, to form an isolation structure SDB, the gate pattern GE is removed and first and second channel patterns CH1 and CH2 and the first and second active patterns AP1 and AP2 are etched to a certain depth on the upper surface to form the third recesses RS3.

The third recess RS3 may penetrate the first and second interlayer insulating layers 110 and 120, the gate capping pattern GP, the gate pattern GE, the first and second channel patterns CH1 and CH2, or a combination thereof, in the third direction D3. In this case, when the gate capping pattern GP, the gate pattern GE, and the first and second channel patterns CH1 and CH2 located around the third recesses RS3 are completely removed during the formation of the third recess RS3,

the isolation structure SDB formed in the subsequent process may penetrate the first and second interlayer insulating layers 110 and 120, and a lower surface LS_SDB of the isolation structure SDB may be located inside the first and second active patterns AP1 and AP2. In another example, when the gate capping pattern GP, the gate pattern GE, and the first and second channel patterns CH1 and CH2 located around the third recess RS3 are not completely removed during the formation of the third recess RS3,

the isolation structure SDB formed in a subsequent process may penetrate the first and second interlayer insulating layers 110 and 120, the gate capping pattern GP, the gate pattern GE, and the first and second channel patterns CH1 and CH2, and the lower surface LS_SDB of the isolation structure SDB may be located inside the first and second active patterns AP1 and AP2. In this case, next to the second direction D2 of the isolation structure SDB, there may remain at least some structures of the gate capping pattern (GP), the gate pattern (GE), and the first and second channel patterns (CH1, CH2) that are not removed upon formation of the third recess (RS3). Furthermore, when a gate insulating layer GI is interposed between the first to third portions PO1 to PO3 of the gate pattern GE and the first and second source/drain patterns SD1 and SD2,

a portion of the gate insulating layer GI may remain next to the isolation structure SDB in the second direction D2, for example, between the isolation structure SDB and the first and second source/drain patterns SD1 and SD2.

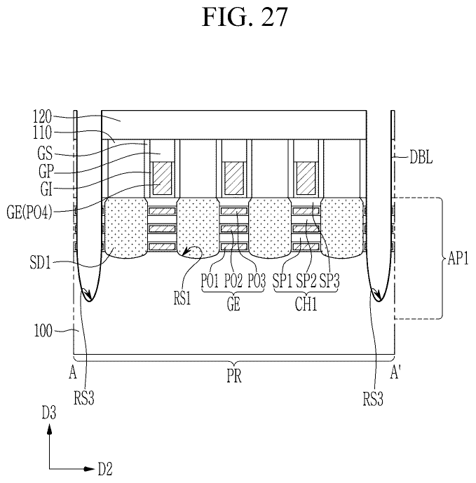

FIG. 27 is a cross-sectional view taken along lines A-A′ in FIG. 1. In this case, a cross-sectional view taken along line B-B′ of FIG. 1 may be substantially the same as FIG. 27 so it is omitted. Also, in the process described in FIG. 27, a cross-sectional view taken along line C-C′ of FIG. 1 is omitted as it may be substantially unchanged from FIG. 24. Also, in the process described in FIG. 27, a cross-sectional view taken along lines D-D′ of FIG. 1 is omitted as it may be substantially unchanged from FIG. 25.

Referring to FIG. 27, an insulating liner DBL is formed inside the third recess RS3.

In one example, the insulating liner DBL may be conformally formed along the inner surface of the third recess RS3. For example, the insulating liner DBL may be formed through deposition processes, such as a CVD process and an ALD process.

The process of forming the insulating liner DBL within the third recess RS3 may include a planarization process to remove the insulating liner DBL located on the upper surface of the first interlayer insulating layer 110 after forming the insulating liner DBL within the third recess RS3. For example, the planarization process may include, but is not limited to, a CMP process, and may be varied.

In one example, the insulating liner DBL may be formed of and/or include an insulating material that does not include oxygen (O) to prevent oxygen (O) or carbon (C) included in the interfacial layer DBO from being diffused into the first and second channel patterns CH1 and CH2 during subsequent processing, and may include, for example, silicon nitride (SiN), silicon carbon nitride (SiCN), or a combination thereof.

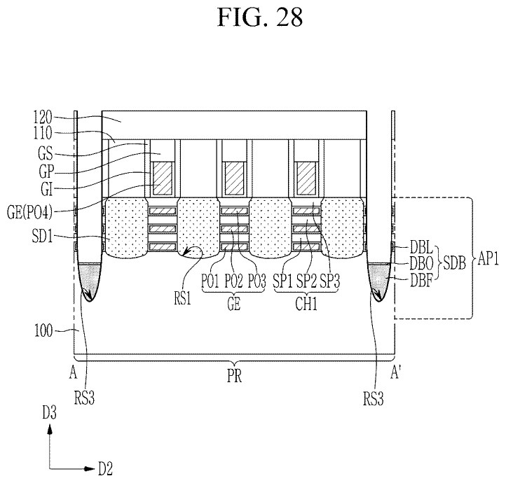

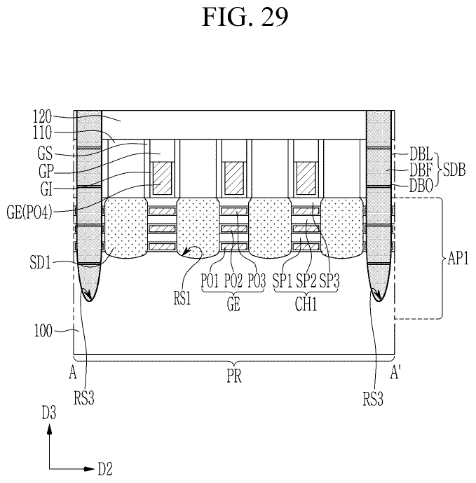

FIGS. 28 and 29 are cross-sectional views taken along lines A-A′ in FIG. 1. In this case, a cross-sectional view taken along line B-B′ of FIG. 1 is omitted as it may be substantially the same as FIGS. 28 and 29. Also, in the process described in FIGS. 28 and 29, a cross-sectional view taken along line C-C′ in FIG. 1 is omitted as it may be substantially unchanged from FIG. 24. Also, in the process described in FIGS. 28 and 29, a cross-sectional view taken along line D-D′ of FIG. 1 is omitted from FIG. 25 as it may be substantially unchanged. Referring to FIG. 28, an insulating pattern DBF is formed inside the third recess RS3 in which the insulating liner DBL is formed, and an interfacial layer DBO is formed on the insulating pattern DBF.

In one example, the insulating pattern DBF may be formed by depositing a fluidized layer to fill a portion of the third recess RS3 inside the third recess RS3 in which the insulating liner DBL is formed and curing the fluidized layer. In the process of curing the fluidized layer, an interfacial layer DBO is formed on the insulating pattern DBF. The interfacial layer DBO may have a higher content (% atoms) of oxygen (O), carbon (C), or both oxygen (O) and carbon (C) than the insulating patterns DBF. Repeating the cycle process of deposition and curing of the fluidized layer may form the insulating structures DBF and DBO including at least two insulating patterns DBF stacked in the third direction D3 within the third recess RS3, and the interfacial layer DBO located between the insulating patterns DBF, as shown in FIG. 29.

In one example, forming the insulating pattern DBF and the interfacial layer DBO may include depositing a fluidized layer by applying a silicon-nitrogen precursor and plasma (for example, ammonia plasma) within the third recess RS3, and curing the fluidized layer.

The silicon-nitrogen precursor and the plasma reactants may simultaneously flow into the third recess RS3. Alternatively, the silicon-nitrogen precursor and the plasma reactants may be mixed within the third recess RS3, or may be mixed prior to entering the third recess RS3.

The silicon-nitrogen precursor may include, for example, a silane-based precursor or a silazane-based precursor. Silane-based precursors may include silanes, halogenated silanes, organosilanes, or combinations thereof, for example, silanes may include silane (SiH₄), disilane (Si₂H₆), trisilane (Si₃H₈), tetrasilane (Si₄H₁₀), polychlorosilane, or combinations thereof. Silazane-based precursors may include trisilylamine (TSA), hexamethyldisilazane (HMDS), tetrakis(dimethylamino) silane, bis(diethylamino) silane, tris(dimethyl-amino) chlorosilane, or combinations thereof.

The silicon-nitrogen precursor may further include a nitrogen-based radical precursor. The nitrogen-based radical precursor may include nitrogen (N₂), nitrous oxide (N₂O), nitric oxide (NO), nitrogen dioxide (NO₂), ammonia (NH₃), or combinations thereof. For example, the nitrogen-based radical precursor may be activated prior to the introduction into the deposition chamber by using a remote plasma source, such as Capacitively-Coupled Plasma (CCP) or Inductively-Coupled Plasma (ICP).

The silicon-nitrogen precursor may be supplied in one or more pulses or continuously. In one example, the flow rate of the silicon-nitrogen precursor may be from 1 standard cubic centimeter per minute (sccm) to 1000 sccm, such as from 2 sccm to 500 sccm, from 3 sccm to 200 sccm, from 5 sccm to 100 sccm, from 10 sccm to 50 sccm, or from 15 sccm to 25 sccm.

The fluidized layer may be deposited within the third recess RS3 on the substrate 100 maintained at a predetermined suitable temperature. In one example, the substrate 100 may be maintained at a temperature of −100° C. to 25° C., such as −75° C. to 20° C., −50° C. to 10° C., or −25° C. to 0° C.

The fluidized layer may be formed at a predetermined suitable pressure. In one example, the pressure used to form the fluidized layer may be 0.5 Torr to 50 Torr, 0.75 Torr to 25 Torr, 1 Torr to 10 Torr, 2 Torr to 8 Torr, or 3 Torr to 6 Torr.

In one example, the deposited fluidized layer may be cured by plasma in a plasma chamber. The plasma chamber may be a predetermined suitable chamber utilizing plasma or plasma-assisted technology. The plasma chamber may generate high-density plasma at high temperatures, and may cure a fluidized layer. The plasma may be generated at a predetermined suitable location. The plasma may be generated or ignited within the processing chamber (for example, direct plasma), or may be generated outside of the processing chamber and flow into the processing chamber (for example, remote plasma).

Depending on the material, plasma treatment may be performed in a nitrogen-containing atmosphere. In one example, a nitrogen-containing atmosphere may be generated by introducing one or more nitrogen-containing gas, for example, nitrogen (N₂), ammonia (NH₃), or a combination thereof, into the plasma chamber. Optionally, inert gas, such as argon, hydrogen, or helium, may be introduced into the plasma chamber.

In one example, the plasma chamber may be an inductively coupled plasma (ICP) chamber. In this case, the plasma chamber may have a plasma source controller to control the supply of inductively coupled RF power, which determines the plasma density (source power), and a bias controller to control the supply of DC power or RF power used to generate a bias voltage on the substrate surface (bias power).

In one example, the pressure in the ICP chamber may be from 1 milli-Torr (mTorr) to 10 Torr, such as from 2 mTorr to 1 Torr, or from 5 mTorr to 88 mTorr. The source power may be from 50 watts (W) to 650 W, such as from 100 W to 500 W, or from 250 W to 450 W. The source power may be applied in the radio frequency (RF) range of 30 MHz to 60 MHz. The bias power provided to the substrate support of the ICP chamber may be from 10 W to 450 W, such as 50 W to 300 W, or 100 W to 200 W. The bias power may be applied in the RF range of 10 MHz to 30 MHz. The substrate temperature may be 550° C. or less, such as 300° C. to 500° C. The gas flow of the nitrogen-containing gas may be from 60 sccm to 5000 sccm, such as from 100 sccm to 2200 sccm, or from 300 sccm to 1000 sccm. The gas flow of the inert gas may be from 5 sccm to 250 sccm, such as from 10 sccm to 150 sccm, or from 20 sccm to 100 sccm. The processing time may be 10 seconds to 120 seconds, such as 30 seconds to 90 seconds, or 45 seconds to 60 seconds.

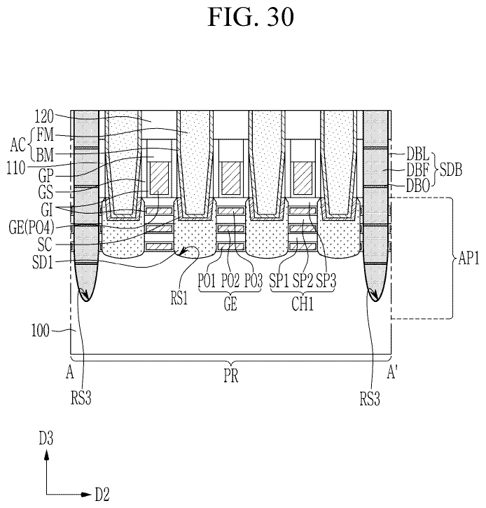

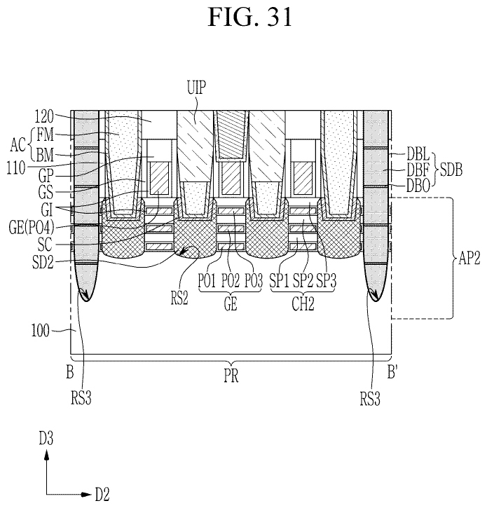

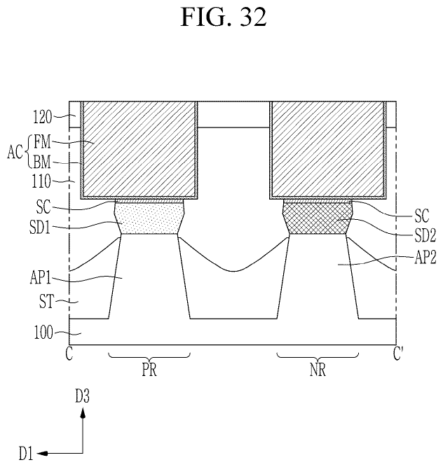

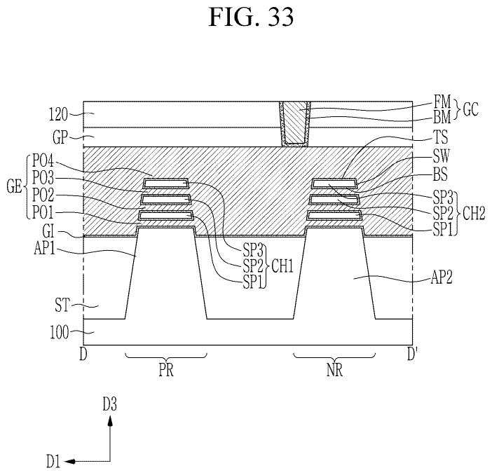

FIG. 30 is a cross-sectional view taken along line A-A′ of FIG. 1. FIG. 31 is a cross-sectional view taken along line B-B′ in FIG. 1. FIG. 32 is a cross-sectional view taken along line C-C′ in FIG. 1. FIG. 33 is a cross-sectional view taken along lines D-D′ in FIG. 1.

Referring to FIGS. 30 to 33, an active contact AC and a gate contact GC are formed.

First, an active contact AC may be formed that penetrates through the first and second interlayer insulating layers 110 and 120 and is electrically connected to the first and second source/drain patterns SD1 and SD2. Additionally, a gate contact GC may be formed that penetrates the second interlayer insulating layer 120 and the gate capping pattern GP to be electrically connected with the gate pattern GE.

In one example, a contact hole may be formed that penetrates through the first and second interlayer insulating layers 110 and 120 to expose the first and second source/drain patterns SD1 and SD2. The contact hole is then filled to form the active contact AC that is electrically connected to the first and second source/drain patterns SD1 and SD2. For example, a barrier pattern BM and a conductive pattern FM may be formed sequentially within a contact hole.

Next, a gate contact GC is formed within the second interlayer insulating layer 120 and the gate capping pattern GP.

First, a contact hole may be formed that penetrates through the second interlayer insulating layer 120 and the gate capping pattern GP to expose the fourth portion PO4 of the gate pattern GE.

Subsequently, the contact hole is filled to form a gate contact GC that is electrically connected to the fourth portion PO4 of the gate pattern GE. For example, a barrier pattern BM and a conductive pattern FM may be formed sequentially within a contact hole.

Referring again to FIGS. 2 to 5, a third interlayer insulating layer 130 including a first metal layer M1 electrically connected with the active contact AC and the gate contact GC is formed on the top surfaces of the second interlayer insulating layer 120 and the gate capping pattern GP.

Furthermore, a fourth interlayer insulating layer 140 which includes a second metal layer M2 electrically connected to the first metal layer M1 is formed on the upper surface of the third interlayer insulating layer 130.

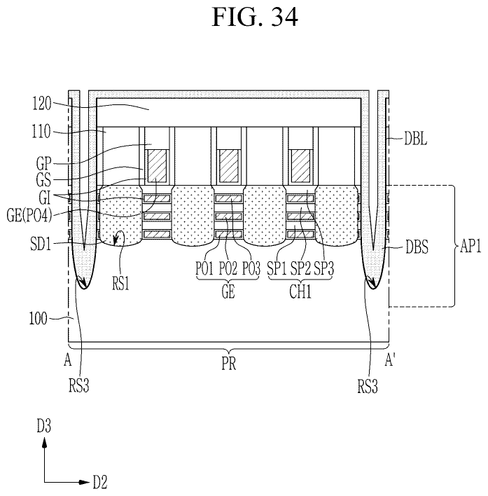

FIGS. 34 to 37 are cross-sectional views illustrating a method of manufacturing a semiconductor device according to another embodiment

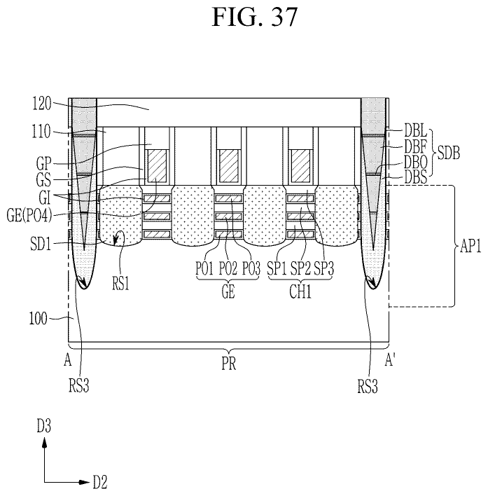

FIGS. 34 and 37 are cross-sectional views taken along line A-A′ of FIG. 1, corresponding to FIGS. 28 and 29 for the different embodiment. In this case, a cross-sectional view taken along the line B-B′ of FIG. 1 may be substantially the same as FIGS. 34 to 37 and is therefore omitted. Also, in the process described in FIGS. 34 to 37, a cross-sectional view taken along line C-C′ of FIG. 1 is omitted as it may be substantially unchanged from FIG. 24. Also, in the process described in FIGS. 34 to 37, a cross-sectional view taken along line D-D′ of FIG. 1 is omitted as it may be substantially unchanged from FIG. 25.

In the following description, configurations and elements that are the same as or similar to the configurations and element described previously may bereferred to by the same reference numerals and redundant descriptions may be omitted or simplified. The follow description serves to emphasize the differences with the previously described embodiments.

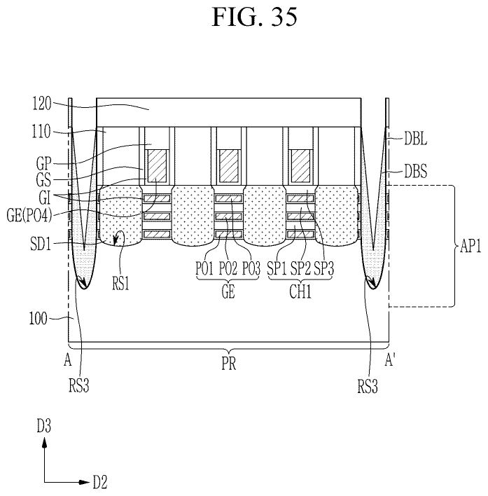

Referring to FIGS. 34 and 35, an insulating spacer DBS is formed inside a third recess RS3 in which an insulating liner DBL is formed.

First, the insulating spacer DBS may be formed conformally along an inner surface of the third recess RS3 in which the insulating liner DBL is formed. For example, the insulating spacers DBS may be formed through deposition processes, such as a CVD process, and an ALD processes.

In this case, a length in the second direction D2, that is, a thickness, of the sidewall portion DBS_S of the insulating spacer DBS may be larger than a length of an insulating liner DBL in the second direction D2 and smaller than a length of an isolation structure SDB in the second direction D2, that is, half a linewidth of a he third recess RS3. Accordingly, the insulating spacer DBS May have a lower end portion DBS_L located at the lower portion of the isolation structure SDB and sidewall portions DBS_S extending in the third direction D3 from the lower end portion DBS_L.

In one example, the insulating spacer DBS may be formed of and/or include an insulating material with better gap fill properties than the insulating liner DBL, such as silicon nitride (SiN), silicon nitride oxide (SiON), silicon carbide (SiCN), or a combination thereof.

Next, through a planarization process, the insulating spacer DBS located on the top surface of a first interlayer insulating layer 110 may be removed. For example, the planarization process may include, but is not limited to, a CMP process, and may be varied.

Next, chamfering is performed on the insulating spacer DBS to remove the insulating spacer DBS on the upper portion of the third recess RS3 to increase the linewidth of the third recess RS3.

Accordingly, the length in the second direction D2, that is, the thickness, of the sidewall portion DBS_S of the insulating spacer DBS may decrease toward the third direction D3. Further, the sidewall portion DBS_S of the insulating spacer DBS do not extend to the upper end of the third recess RS3, and the overall shape of the top surface of the insulating spacer DBS, that is, the surface in contact with the insulating patterns DBF, may be V-shaped.

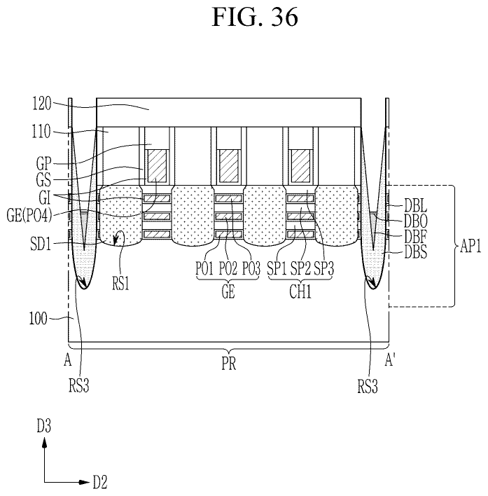

Referring to FIGS. 36 and 37, the insulating pattern DBF is formed inside the third recess RS3 in which the insulating spacer DBS is formed, and an interfacial layer DBO is formed on the insulating pattern DBF.

In one example, the dielectric pattern DBF may be formed by depositing a fluidized layer to fill a portion of the third recess RS3 inside the third recess RS3 in which the insulating spacer DBS is formed and curing the fluidized layer. In the process of curing the fluidized layer, an interfacial layer DBO is formed on the insulating pattern DBF. The interfacial layer DBO may have a higher content (% atoms) of oxygen (O), carbon (C), or both oxygen (O) and carbon (C) than the insulating patterns DBF. By repeating the cycle process of the fluidized layer deposition and curing, the insulating structures DBF and DBO may fill the inner region of the third recess RS3 left after forming the insulating spacer DBS, as illustrated in FIG. 37. For example, the insulating spacer DBS may surround at least a portion of the insulating structures DBF and DBO. For example, the insulating pattern DBF of the insulating structures DBF and DBO may be located on the lower end portion DBS_L of the insulating spacer DBS, and the insulating pattern DBF may be located between the sidewall portions DBS_S of the insulating spacer DBS.

The method of depositing the fluidized layer and curing the fluidized layer to form the insulating pattern DBF and the interfacial layer DBO may be the same as described in FIGS. 28 and 29 and the description is not repeated here.

Although embodiments of the present disclosure have been described in detail, the scope of the inventive concept is not limited to the described embodiments. Various changes and modifications of the present disclosure are possible and the scope of the inventive concept is defined in the accompanying claims.

### DESCRIPTION OF SYMBOLS

100: Substrate
AP1, AP2: First and second active patterns
CH1, CH2: First and second channel patterns
GE: Gate pattern
SD1, SD2: First and second source/drain patterns
110: First interlayer insulating layer
120: Second interlayer insulating layer
130: Third interlayer insulating layer
140: Fourth interlayer insulating layer
AC: Active contact
GC: Gate contact
M1: First metal layer
M2: Second metal layer
SDB: Isolation structure
DBL: Insulating liner
DBF: Insulating pattern
DBO: Interfacial layer
DBS: Insulating spacer

What is claimed is:

1. A semiconductor device comprising:
an active pattern located on a substrate, the active pattern spaced apart from other active patterns in a first direction and extending in a second direction different from the first direction;
source/drain patterns located on the active pattern and each source/drain pattern spaced apart from one another in the second direction;
a channel pattern located between a first source/drain pattern and a second source/drain pattern of the source/drain patterns;
a gate pattern extending between the adjacent source/drain patterns in the first direction and surrounding at least a portion of the channel pattern; and
an isolation structure extending in the first direction, the isolation structure located outside the source/drain patterns in the second direction and extending into the active pattern in a third direction that is different from the first and second directions,
wherein the isolation structure includes insulating patterns stacked in the third direction, an interfacial layer located between adjacent insulating patterns, and an insulating liner surrounding the insulating patterns.

2. The semiconductor device of claim 1, wherein:
the insulating pattern includes silicon nitride (SiN), silicon nitride oxide (SiON), silicon carbon nitride (SiCN), or a combination thereof.

3. The semiconductor device of claim 2, wherein:
the insulating pattern is formed of a material that has that has a concentration of, from 30 at % to 60 at % of the silicon (Si), from 30 at % to 60 at % of the nitrogen (N), from 0 at % to 5 at % of the oxygen (O), and from 0 at % to 50 at % of the carbon (C).

4. The semiconductor device of claim 1, wherein:
the interfacial layer includes silicon (Si) and nitrogen (N), and
the interfacial layer further includes oxygen (O), carbon (C), or both oxygen (O) and carbon (C).

5. The semiconductor device of claim 4, wherein:
the interfacial layer is formed of a material that has that has a concentration of from 20 at % to 60 at % of the silicon (Si), from 30 at % to 60 at % of the nitrogen (N), from between 0 to 20 at % of the oxygen (O), and from between 0 at % to 50 at % of the carbon (C).

6. The semiconductor device of claim 1, wherein:
the insulating liner includes an insulating material that includes silicon nitride (SiN), silicon carbonitride (SiCN), or a combination thereof, and does not include oxygen (O).

7. The semiconductor device of claim 1, wherein:
the isolation structure has a void less than 2 nm, and
the isolation structure does not have a void in the range of 2 nm to 10 nm.

8. The semiconductor device of claim 1, wherein:
the isolation structure includes between 2 to 20 insulating patterns, and
between 1 to 19 interfacial layers.

9. The semiconductor device of claim 1, wherein:
a length of at least one insulating pattern in the third direction is 1 nm to 150 nm.

10. The semiconductor device of claim 1, wherein:
a length of the insulating liner in the second direction is 2 nm to 5 nm.

11. The semiconductor device of claim 1, further comprising:
a first interlayer insulating layer located on the substrate and covering the source/drain pattern;
a gate capping pattern located on the gate pattern; and
a second interlayer insulating layer located on the first interlayer insulating layer and the gate capping pattern,
wherein the isolation structure penetrates through the first interlayer insulating layer, the second interlayer insulating layer, the gate capping pattern, the gate pattern, the channel pattern, or a combination thereof, in the third direction.

12. A semiconductor device comprising:
an active pattern located on a substrate, the active pattern spaced apart from other active patterns in a first direction and extending in a second direction different from the first direction;
source/drain patterns located on the active pattern and each source/drain pattern spaced apart from one another in the second direction;
a channel pattern located between a first source/drain pattern and a second source/drain pattern of the source/drain patterns;
a gate pattern extending between the first source/drain pattern and the second source/drain pattern in the first direction and surrounding at least a portion of the channel pattern; and
an isolation structure extending in the first direction, located outside the source/drain patterns in the second direction, and extending into the active pattern in a third direction that is different from the first and second directions,
wherein the isolation structure includes insulating patterns stacked in the third direction, an interfacial layer located between the insulating patterns, an insulating liner surrounding the insulating patterns, and an insulating spacer located between the insulating patterns and the insulating liner.

13. The semiconductor device of claim 12, wherein:
the insulating spacer has a lower end portion located in a lower portion of the isolation structure and sidewall portions extending from the lower end portion in the third direction.

14. The semiconductor device of claim 13, wherein:
a first insulating pattern of the insulating patterns is located on the lower end portion of the insulating spacer,
the first insulating pattern is located between the sidewall portions of the insulating spacer.

15. The semiconductor device of claim 12, wherein:
a length of a sidewall portion of the insulating spacer in the second direction decreases toward the third direction.

16. A semiconductor device comprising:
an active pattern located on a substrate, the active pattern spaced apart from other active patterns in a first direction and extending in a second direction different from the first direction;
source/drain patterns located on the active pattern and each source/drain pattern spaced apart from one another in the second direction;
a channel pattern located between a first source/drain pattern and a second source/drain pattern of the source/drain patterns;
a gate pattern extending between the first source/drain pattern and the second source/drain pattern in the first direction and surrounding at least a portion of the channel pattern; and
an isolation structure extending in the first direction, the isolation structure located outside the source/drain patterns in the second direction, and extending into the active pattern in a third direction that is different from the first and second directions,
wherein the isolation structure includes an insulating structure having a first portion and a second portion having different contents (atom %) of oxygen (O), carbon (C), or both oxygen (O) and carbon (C), and an insulating liner surrounding the insulating structure.

17. The semiconductor device of claim 16, wherein:
the first portion and the second portion include silicon (Si) and nitrogen (N), and
the first portion and the second portion further include oxygen (O), carbon (C), or both oxygen (O) and carbon (C).

18. The semiconductor device of claim 17, wherein:
the first portion is formed of a material that has that has a concentration of from 30 at % to 60 at % of the silicon (Si), from 30 at % to 60 at % of the nitrogen (N), between 0 at % to 5 at % of the oxygen (O), and between 0 at % to 50 at % of the carbon (C).

19. The semiconductor device of claim 17, wherein:
the second portion is formed of a material that has a concentration of from 20 at % to 60 at % of the silicon (Si), from 30 at % to 60 at % of the nitrogen (N), between 0 at % to 20 at % of the oxygen (O), and between 0 at % to 50 at % of the carbon (C).

20. The semiconductor device of claim 16, wherein:
the isolation structure has a void greater less than 2 nm, and
the isolation structure does not have a void in the range of 2 nm to 10 nm.
